(19) United States
(12) Patent Application Publication
(10) Pub. No.: US 2026/0300160 A1
(43) Pub. Date: Oct. 1, 2026

(54) MEMORY SYSTEM, OPERATION METHOD THEREOF AND CONTROLLER

(71) Applicant: YANGTZE MEMORY TECHNOLOGIES CO., LTD., Wuhan (CN)

(72) Inventors: Xingwei TANG, Wuhan (CN); Guangchang YE, Wuhan (CN); Lu GUO, Wuhan (CN)

(21) Appl. No.: 19/291,003

(22) Filed: Aug. 5, 2025

(30) Foreign Application Priority Data
Mar. 31, 2025 (CN) 2025103977914

(51) Int. Cl. G06F 12/02

(52) U.S. Cl. CPC G06F 12/0246; G06F 2212/1016

(57) ABSTRACT

Examples of the disclosure provide a memory system, including: at least one memory device and a controller coupled to and configured to control the memory device, the memory device includes a memory cell array and a peripheral circuit coupled thereto, the memory cell array includes a plurality of memory cells, in which a preset number of memory cells form a codeword; the peripheral circuit is configured to: perform a read operation on a reference codeword to obtain a first result, which is used as a VT indicator; and the controller is configured to: obtain at least one offset prediction according to the VT indicator in combination with a mapping table, the mapping table includes a mapping relationship between the VT indicator and the offset prediction; and determine, according to the offset prediction, a valley voltage being used as a read voltage for performing the read operation on a target codeword.

### CROSS-REFERENCE TO RELATED APPLICATIONS

The present disclosure claims priority to Chinese Patent Application No. 2025103977914, which was filed Mar. 31, 2025, and is hereby incorporated herein by reference in its entirety.

### TECHNICAL FIELD

Examples of the present disclosure relate to the field of semiconductor technologies, including but not limited to a memory system, an operation method thereof, and a controller.

### BACKGROUND

With the development of technology, the market scale of the integrated circuit industry is increasing, and in the entire integrated circuit industry, process and technology of non-volatile memory devices have been rapidly developed in recent years, wherein the application of NAND memory devices is particularly extensive. A NAND memory device realizes the function of data storage by trapping and storing charges in a gate dielectric layer of a memory cell contained therein. However, as the usage time increases, the charges stored in the memory cell will change with the increase in usage time, repeated read operations, cross temperatures, etc., thereby affecting the correctness of reading the data stored in the memory cell.

### SUMMARY

In view of this, examples of the present disclosure provide a memory system, an operation method thereof, and a controller.

In a first aspect, an example of the present disclosure provides a memory system, including: at least one memory device and a controller coupled to the memory device and configured to control the memory device, wherein the memory device includes a memory cell array and a peripheral circuit coupled to the memory cell array, the memory cell array includes a plurality of memory cells, and a preset number of memory cells in the plurality of memory cells form a codeword; the peripheral circuit is configured to: perform a read operation on a reference codeword to obtain a first result, and use the first result as a VT indicator; the first result is configured to represent a number of bits that are flipped between two read results of the reference codeword at a first read voltage and a second read voltage, and a difference between the first read voltage and the second read voltage is less than a preset voltage; and the controller is configured to: obtain at least one offset prediction according to the VT indicator in combination with a mapping table, wherein the mapping table includes a mapping relationship between the VT indicator and the offset prediction; and determine a valley voltage according to the offset prediction, wherein the valley voltage is used as a read voltage for performing the read operation on a target codeword.

In some examples, the memory cell has M memory bits, the M memory bits correspond to (2^{M}−1) read levels, the (2^{M}−1) read levels include a reference read level, and M is an integer greater than or equal to 2; and the peripheral circuit is configured to: obtain, in a single level read mode, a first result corresponding to the reference codeword at a default read voltage of the reference read level, and use the first result as the VT indicator, wherein the default read voltage is a read voltage when a threshold voltage has not shifted.

In some examples, the controller is configured to: obtain a VT indicator grade corresponding to the VT indicator according to the VT indicator, wherein the VT indicator grade is configured to represent one or more continuously arranged VT indicators.

In some examples, the controller is configured to: obtain at least one offset prediction according to the VT indicator grade and a target read level of the target codeword in combination with the mapping table, wherein the mapping table includes a mapping relationship among the VT indicator grade, the target read level, and the offset prediction.

In some examples, the controller is configured to obtain a word line group corresponding to the target codeword according to a position of the target codeword in the memory cell array, in which the word line group is configured to represent the one or more adjacently disposed word lines.

In some examples, the controller is configured to: obtain at least one offset prediction according to the VT indicator grade, the target read level of the target codeword, and the word line group corresponding to the target codeword in combination with the mapping table, wherein the mapping table includes a mapping relationship among the VT indicator grade, the target read level, the word line group, and the offset prediction.

In some examples, the at least one offset prediction includes two offset predictions, and two preset first results corresponding to the two offset predictions are both within a preset interval; the controller is configured to: obtain two target read voltages according to the two offset predictions; the peripheral circuit is configured to: obtain a first result corresponding to the target codeword at one target read voltage, and obtain a first result corresponding to the target codeword at the other target read voltage; and the controller is configured to: obtain the valley voltage according to the two target read voltages and the two first results corresponding to the two target read voltages in combination with a preset function model.

In some examples, the preset function model includes a quadratic function model, and the quadratic function model includes the following function expression: y=a(x+b)²+c, wherein y is the first result, x is the target read voltage, b is configured to represent a prediction parameter, a is a first parameter, and c is a second parameter.

In some examples, the first parameter is a variable, and the second parameter is a constant; and the controller is configured to: obtain the prediction parameter according to the two target read voltages and the two first results corresponding to the two target read voltages in combination with the quadratic function model; and use the prediction parameter as the valley voltage.

In some examples, the at least one offset prediction includes one offset prediction; and the controller is configured to obtain the valley voltage according to the one offset prediction.

In some examples, the at least one offset prediction includes two offset predictions, and two preset first results corresponding to the two offset predictions are both within a preset interval; and the controller is configured to: obtain two target read voltages according to the two offset predictions; and obtain the valley voltage according to the two target read voltages and the two preset first results corresponding to the two target read voltages in combination with a preset function model.

In some examples, the peripheral circuit is configured to perform a read operation on the target codeword according to the valley voltage to obtain target data; and the controller is configured to obtain the target data.

In some examples, the peripheral circuit is configured to: read the stored data of the reference codeword at the first read voltage to obtain a second result; read the stored data of the reference codeword at the second read voltage to obtain a third result; perform a logical operation on the second result and the third result to obtain a fourth result; and count a number of bits in the fourth result representing the flipping of the third result compared to the second result to obtain the first result.

In a second aspect, an example of the present disclosure provides a controller, wherein the controller is coupled to at least one memory device, the memory device includes a memory cell array and a peripheral circuit coupled to the memory cell array, the memory cell array includes a plurality of memory cells, and a preset number of memory cells in the plurality of memory cells form a codeword; the controller is configured to: perform a read operation on a reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage; obtain at least one offset prediction according to the VT indicator in combination with a mapping table, wherein the mapping table includes a mapping relationship between the VT indicator and the offset prediction; and determine a valley voltage according to the offset prediction, wherein the valley voltage is used as a read voltage for performing the read operation on a target codeword.

In some examples, the memory cell has M memory bits, the M memory bits correspond to (2^{M}−1) read levels, the (2^{M}−1) read levels include a reference read level, and M is an integer greater than or equal to 2; and the controller is configured to: obtain in a single level read mode, a first result corresponding to the reference codeword at a default read voltage of the reference read level; and use the first result as the VT indicator, wherein the default read voltage is a read voltage when a threshold voltage has not shifted.

In some examples, the controller is configured to: obtain a VT indicator grade corresponding to the VT indicator according to the VT indicator, wherein the VT indicator grade is configured to represent one or more continuously arranged VT indicators.

In some examples, the controller is configured to: obtain at least one offset prediction according to the VT indicator grade and a target read level of the target codeword in combination with the mapping table, wherein the mapping table includes a mapping relationship among the VT indicator grade, the target read level, and the offset prediction.

In some examples, the controller is configured to obtain a word line group corresponding to the target codeword according to a position of the target codeword in the memory cell array, wherein the word line group is configured to represent the one or more adjacently disposed word lines.

In some examples, the controller is configured to: obtain at least one offset prediction according to the VT indicator grade, the target read level of the target codeword, and the word line group corresponding to the target codeword in combination with the mapping table, wherein the mapping table includes a mapping relationship among the VT indicator grade, the target read level, the word line group, and the offset prediction.

In some examples, the at least one offset prediction includes two offset predictions, and two preset first results corresponding to the two offset predictions are both within a preset interval; and the controller is configured to: obtain two target read voltages according to the two offset predictions; obtain a first result corresponding to the target codeword at one target read voltage; obtain a first result corresponding to the target codeword at the other target read voltage; and obtain the valley voltage according to the two target read voltages and the two first results corresponding to the two target read voltages in combination with a preset function model.

In some examples, the preset function model includes a quadratic function model, and the quadratic function model includes the following function expression: y=a(x+b)²+c, wherein y is the first result, x is the target read voltage, b is configured to represent a prediction parameter, a is a first parameter, and c is a second parameter.

In some examples, the first parameter is a variable, and the second parameter is a constant; and the controller is configured to: obtain the prediction parameter according to the two target read voltages and the two first results corresponding to the two target read voltages in combination with the quadratic function model; and use the prediction parameter as the valley voltage.

In some examples, the at least one offset prediction includes one offset prediction; and the controller is configured to obtain the valley voltage according to the one offset prediction.

In some examples, the at least one offset prediction includes two offset predictions, and two preset first results corresponding to the two offset predictions are both within a preset interval; and the controller is configured to: obtain two target read voltages according to the two offset predictions; and obtain the valley voltage according to the two target read voltages and the two preset first results corresponding to the two target read voltages in combination with a preset function model.

In some examples, the controller is configured to perform a read operation on the target codeword according to the valley voltage to obtain the target data.

In a third aspect, an example of the present disclosure provides an operation method of a memory system, wherein the memory system includes: at least one memory device and a controller coupled to the memory device and configured to control the memory device, wherein the memory device includes a memory cell array and a peripheral circuit coupled to the memory cell array, the memory cell array includes a plurality of memory cells, and a preset number of memory cells in the plurality of memory cells form a codeword; and the operation method includes: performing, by the peripheral circuit, a read operation on a reference codeword to obtain a first result, and using the first result as a VT indicator, wherein the first result is configured to represent a number of bits that are flipped between two read results of the reference codeword at a first read voltage and a second read voltage, a difference between the first read voltage and the second read voltage is less than a preset voltage; obtaining, by the controller, at least one offset prediction according to the VT indicator in combination with a mapping table, wherein the mapping table includes a mapping relationship between the VT indicator and the offset prediction; and determining a valley voltage according to the offset prediction, wherein the valley voltage is used as a read voltage for performing the read operation on a target codeword.

In some examples, the memory cell has M memory bits, the M memory bits correspond to (2^{M}−1) read levels, the (2^{M}−1) read levels include a reference read level, and M is an integer greater than or equal to 2; and the performing, by the peripheral circuit, a read operation on a reference codeword to obtain a first result, and using the first result as a VT indicator includes: obtaining, by the peripheral circuit in a single level read mode, the first result corresponding to the reference codeword at a default read voltage of the reference read level, and using the first result as the VT indicator, wherein the default read voltage is a read voltage when a threshold voltage has not shifted.

In some examples, the operation method further includes: obtaining, by the controller, a VT indicator grade corresponding to the VT indicator according to the VT indicator, wherein the VT indicator grade is configured to represent one or more continuously arranged VT indicators.

In some examples, the obtaining, by the controller, at least one offset prediction according to the VT indicator in combination with a mapping table includes: obtaining, by the controller, at least one offset prediction according to the VT indicator grade and a target read level of the target codeword in combination with the mapping table, wherein the mapping table includes a mapping relationship among the VT indicator grade, the target read level, and the offset prediction.

In some examples, the operation method further includes: obtaining, by the controller, a word line group corresponding to the target codeword according to a position of the target codeword in the memory cell array, wherein the word line group is configured to represent the one or more adjacently disposed word lines.

In some examples, the obtaining, by the controller, at least one offset prediction according to the VT indicator in combination with a mapping table includes: obtaining, by the controller, at least one offset prediction according to the VT indicator grade, a target read level of the target codeword, and the word line group corresponding to the target codeword in combination with the mapping table, wherein the mapping table includes a mapping relationship among the VT indicator grade, the target read level, the word line group, and the offset prediction.

In some examples, the at least one offset prediction includes two offset predictions, and two preset first results corresponding to the two offset predictions are both within a preset interval; and the determining a valley voltage according to the offset predictions includes: obtaining, by the controller, two target read voltages according to the two offset predictions; obtaining, by the peripheral circuit, a first result corresponding to the target codeword at one target read voltage, and a first result corresponding to the target codeword at the other target read voltage; and obtaining, by the controller, the valley voltage according to the two target read voltages and the two first results corresponding to the two target read voltages in combination with a preset function model.

In some examples, the preset function model includes a quadratic function model, and the quadratic function model includes the following function expression: y=a(x+b)²+c, wherein y is the first result, x is the target read voltage, b is configured to represent a prediction parameter, a is a first parameter, and c is a second parameter.

In some examples, the first parameter is a variable, and the second parameter is a constant; and the obtaining, by the controller, the valley voltage according to the two target read voltages and the two first results corresponding to the two target read voltages in combination with a preset function model includes: obtaining the prediction parameter according to the two target read voltages and the two first results corresponding to the two target read voltages in combination with the quadratic function model; and using the prediction parameter as the valley voltage.

In some examples, the at least one offset prediction includes one offset prediction; and the determining a valley voltage according to the offset prediction includes: obtaining the valley voltage according to the one offset prediction.

In some examples, the at least one offset prediction includes two offset predictions, and two preset first results corresponding to the two offset predictions are both within a preset interval; and the determining a valley voltage according to the offset predictions includes: obtaining two target read voltages according to the two offset predictions; and obtaining the valley voltage according to the two target read voltages and the two preset first results corresponding to the two target read voltages in combination with a preset function model.

In some examples, the operation method further includes: performing, by the peripheral circuit, a read operation on the target codeword according to the valley voltage to obtain target data; and obtaining, by the controller, the target data.

In some examples, the performing, by the peripheral circuit, a read operation on a reference codeword to obtain a first result includes: reading stored data of the reference codeword at the first read voltage to obtain a second result; reading the stored data of the reference codeword at the second read voltage to obtain a third result; performing a logical operation on the second result and the third result to obtain a fourth result; and counting a number of bits in the fourth result representing the flipping of the third result compared to the second result, to obtain the first result.

A memory system, an operation method thereof, and a controller are provided. In the examples of the present disclosure, the memory device is used to perform a read operation on the reference codeword to obtain a VT indicator; the controller is used to obtain at least one offset prediction according to the VT indicator in combination with the mapping table; and the valley voltage is obtained according to the offset prediction. In this way, the degree of shift of the threshold voltage can be described by using the VT indicator, thereby improving the efficiency of obtaining the valley voltage.

### BRIEF DESCRIPTION OF THE DRAWINGS

In the drawings, like reference numerals refer to the same or similar components or elements throughout the various figures unless otherwise specified. The figures are not necessarily to scale. It should be understood that these drawings depict only some examples disclosed according to the present application and are not to be considered as limiting the scope of the present application.

FIG. 1 is a block diagram illustrating an electronic apparatus having a memory device according to an example of the present disclosure;

FIG. 2 is a schematic diagram illustrating a memory card having a memory device according to an example of the present disclosure;

FIG. 3 is a schematic diagram illustrating a solid state drive having a memory device according to an example of the disclosure;

FIG. 4 is a schematic diagram illustrating a memory device including a peripheral circuit according to an example of the present disclosure;

FIG. 5 is a schematic cross-sectional view illustrating a memory cell array including memory strings according to an example of the present disclosure;

FIG. 6 is a block diagram illustrating a memory device including a peripheral circuit according to an example of the present disclosure;

FIG. 7 is a schematic diagram of an implementation process of the memory system configured to perform an operation method provided in an example of the present disclosure;

FIG. 8 is a threshold voltage distribution diagram corresponding to memory cells with two memory bits provided in an example of the present disclosure;

FIG. 9 is a threshold voltage distribution diagram corresponding to a memory cell with three memory bits provided in an example of the present disclosure;

FIG. 10 is a threshold voltage distribution diagram corresponding to a memory cell with four memory bits provided in an example of the present disclosure;

FIG. 11 is a threshold voltage distribution diagram corresponding to a memory cell when obtaining a first result as provided in an example of the present disclosure;

FIG. 12 is threshold voltage distribution diagrams corresponding to memory cells at different read levels provided in an example of the present disclosure;

FIG. 13 is a schematic diagram of determining a VT indicator grade provided in an example;

FIG. 14 is a schematic diagram of a mapping table provided by an example of the present disclosure;

FIG. 15 is a schematic flowchart of determining a valley voltage provided by some examples of the present disclosure;

FIG. 16 is a schematic flowchart of determining a valley voltage provided by some other examples of the present disclosure;

FIG. 17 is a schematic diagram of a preset function model provided by some examples of the present disclosure;

FIG. 18 is a schematic diagram of determining a predicted valley voltage according to a preset function model provided by some examples of the present disclosure;

FIG. 19 is a block diagram of a controller provided by some examples of the present disclosure.

### DETAILED DESCRIPTION

The technical solutions in the examples of the present disclosure will be clearly and completely described below with reference to the examples of the present disclosure and the accompanying drawings. Obviously, the described examples are only some examples of the present disclosure, rather than all examples. All other implementations obtained by a person of ordinary skill in the art based on the implementations of the present disclosure without creative efforts shall fall within the protection scope of the present disclosure.

In the following description, numerous specific details are set forth in order to provide a more thorough understanding of the present disclosure. However, it will be apparent to those skilled in the art that the present disclosure may be practiced without one or more of these details. In other examples, in order to avoid confusion with the present disclosure, some technical features known in the art are not described; for example, not all features of actual examples are described herein, and well-known functions and structures are not described in detail.

In the drawings, the sizes of layers, regions, elements and their relative sizes may be exaggerated for clarity. Like numbers refer to like elements throughout.

It will be understood that when an element or layer is referred to as being “on”, “adjacent to”, “connected to” or “coupled to” another element or layer, it can be directly on, adjacent to, connected or coupled to the other element or layer, or intervening elements or layers may be present. In contrast, when an element is referred to as being “directly on,” “directly adjacent to,” “directly connected to,” or “directly coupled to” another element or layer, there are no intervening elements or layers present. It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure. When a second element, component, region, layer or section is discussed, it does not indicate that the first element, component, region, layer or section is necessarily present in the present disclosure.

Spatially relative terms, such as “under”, “below”, “lower”, “beneath”, “above”, “over” and the like, may be used herein for ease of description to describe one element or feature's relationship to another element(s) or feature(s) as illustrated in the figures. It will be understood that the spatially relative terms may encompass different orientations of the device in use or operation in addition to the orientation depicted in the figures. For example, if the device in the figures is turned over, elements or features described as “below” or “under” other elements would then be oriented “above” the other elements or features. Thus, the example terms “below” and “under” can encompass both orientations of above and below. The device may be otherwise oriented (rotated 90 degrees or at other orientations) and the spatially relative descriptors used herein interpreted accordingly.

The terminology used herein is for the purpose of describing particular examples only and is not intended to be limitation to the disclosure. As used herein, the singular forms “a”, “an” and “the” are intended to include the plural forms as well, unless the context clearly indicates otherwise. It will be further understood that the terms “comprises” and/or “includes” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

In order to thoroughly understand the present disclosure, detailed steps and detailed structures are provided in the following description to explain the technical solutions of the present disclosure. Preferred examples of the present disclosure are described in detail below, but the present disclosure may have other implementations in addition to these detailed descriptions.

The memory device in the examples of the present disclosure may include, but is not limited to, a three-dimensional NAND memory device, and for ease of understanding, the three-dimensional NAND memory device is taken as an example for description.

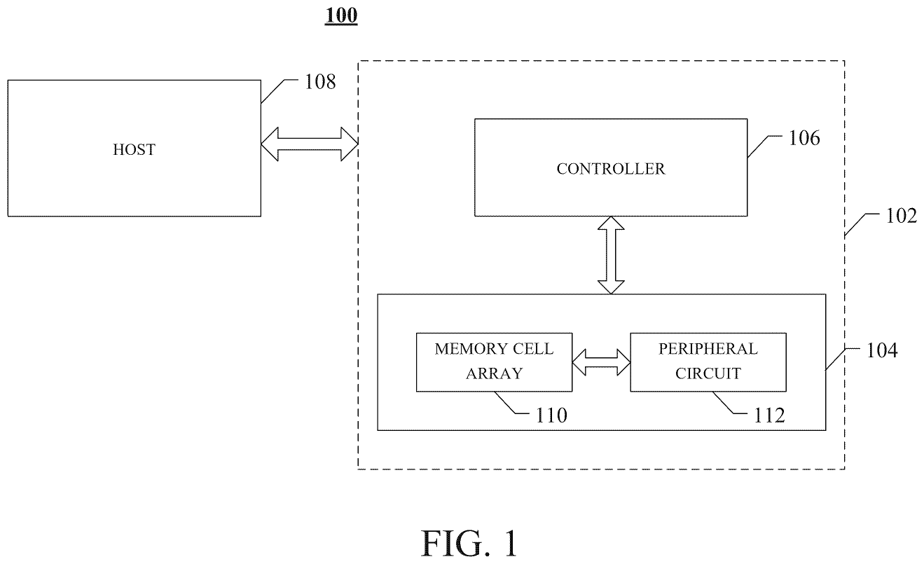

Referring to FIG. 1, which is a block diagram illustrating an electronic apparatus having a memory device according to an example of the present disclosure. As shown in FIG. 1, the electronic apparatus 100 may be a mobile phone, a desktop computer, a laptop computer, a tablet computer, a vehicle computer, a game console, a printer, a positioning v, a wearable electronic apparatus, a smart sensor, a virtual reality (VR) apparatus, an augmented reality (AR) apparatus, or any other suitable electronic apparatus having a memory device therein.

As shown in FIG. 1, the electronic apparatus 100 may include a host 108 and a memory system 102 (as shown by a dashed box in FIG. 1), the memory system 102 has one or more memory devices 104 and a controller 106, and only one memory device 104 is taken as an example in FIG. 1. The host 108 may be a processor (e.g., a central processing unit (CPU)) of the electronic apparatus or a system on chip (SoC) (e.g., an application processor (AP)). The host 108 can be configured to send data to the memory device 104 or receive data from the memory device 104.

In some examples, controller 106 is coupled to the memory device 104 and the host 108, and is configured to control the memory device 104. The controller 106 may manage data stored in the memory device 104 and communicate with the host 108.

In some examples, the controller 106 is designed for operation in low duty cycle environments, for example, Secure Digital (SD) cards, Compact Flash (CF) cards, Universal Serial Bus (USB) flash drives, or other media for use in electronic apparatuses such as personal calculators, digital cameras, mobile phones, etc.

In some examples, the controller 106 is designed to operate in a high duty cycle environment Solid State Drive (SSD) or embedded Multi-Media Card (eMMC), which serve as data storage for mobile apparatus such as smartphones, tablets, laptops, etc. and enterprise storage arrays.

Controller 106 may be configured to control operations of the memory device 104, e.g., read, erase, and program operations. The controller 106 may also be configured to manage various functions with respect to data stored or to be stored in the memory device 104 including, but not limited to, bad block management, garbage collection, logical address to physical address translation, wear leveling, etc. In some examples, the controller 106 is further configured to process an error correcting code (ECC) with respect to data read from the memory device 104 or written to the memory device 104.

The controller 106 may also perform any other suitable functions, such as formatting the memory device 104. The controller 106 may communicate with an external apparatus (e.g., the host 108) according to a particular communication protocol. For example, the controller 106 may communicate with the external apparatus through at least one of various interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a Parallel ATA protocol, a Small Computer System Interface (SCSI) protocol, an Enhanced Small Drive Interface (ESDI) protocol, an Integrated Drive Electronics (IDE) protocol, a Firewire protocol, etc.

The controller 106 and the one or more memory devices 104 may be integrated into various types of storage apparatus, for example, included in the same package (e.g., a Universal Flash Storage (UFS) package or an eMMC package). For example, the memory system 102 may be implemented and packaged into different types of end electronic products.

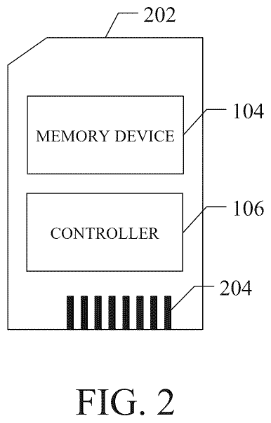

Referring to FIG. 2, which is a schematic diagram illustrating a memory card having a memory device according to an example of the present disclosure. As shown in FIG. 2, a controller 106 and a single memory device 104 may be integrated into a memory card 202. The memory card 202 may include Personal Computer Memory Card International Association (PCMCIA) cards, CF cards, Smart Media (SM) cards, memory sticks, multimedia cards (e.g., MMC, Reduced-Size MMC (RS-MMC), microMMC), SD (e.g., SD, miniSD, microSD, Secure Digital High Capacity (SDHC)) cards, UFS, etc. The memory card 202 may also include a memory card connector 204 that couples the memory card 202 and a host (e.g., the host 108 in FIG. 1).

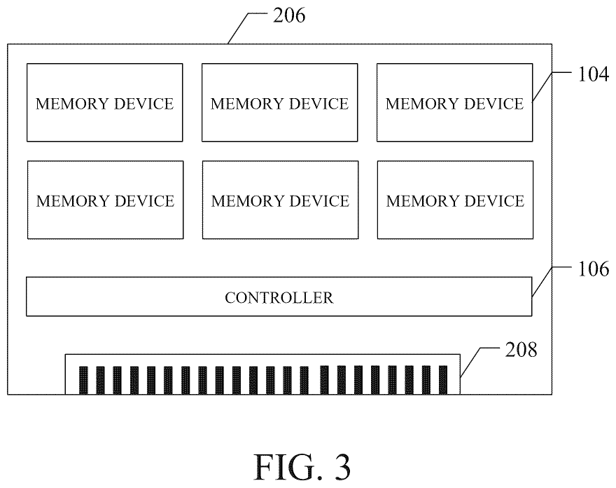

Referring to FIG. 3, which is a schematic diagram illustrating a solid state drive having memory device according to an example of the present disclosure. As shown in FIG. 3, a controller 106 and a plurality of memory devices 104 may be integrated into a solid state drive 206. The solid state drive 206 may also include a solid state drive connector 208 that couples the solid state drive 206 and a host (e.g., the host 108 in FIG. 1). In some examples, the storage capacity and/or operating speed of the solid state drive 206 is greater than the storage capacity and/or operating speed of the memory card 202.

Referring back to FIG. 1, the memory device 104 further includes a memory cell array 110 and a peripheral circuit 112 coupled to the memory cell array 110. The memory cell array 110 may be a NAND flash memory cell array.

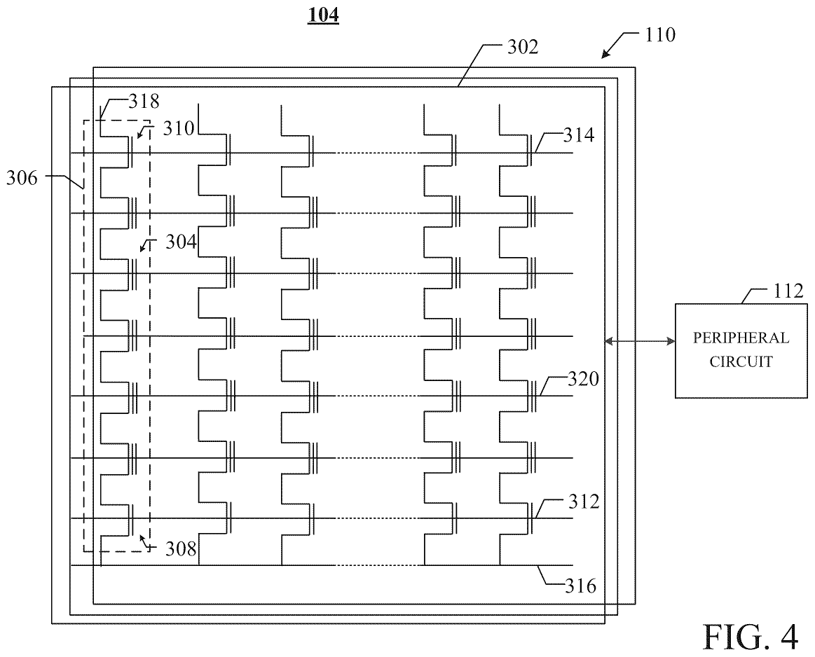

Referring to FIG. 4, which is a schematic diagram illustrating a memory device including a peripheral circuit according to an example of the present disclosure. The memory device 104 may include a memory cell array 110 and a peripheral circuit 112 coupled to the memory cell array 110. The memory cells 304 are provided in the form of an array of memory strings 306, with each memory string 306 (illustrated as a dashed box in FIG. 4) extending vertically above a substrate (not illustrated in FIG. 4). In some examples, each memory string 306 includes a plurality of memory cells 304 coupled in series and vertically stacked. Each memory cell 304 may hold a continuous analog value, e.g., voltage or charge, depending on the number of electrons trapped within a region of the memory cell 304. Each memory cell 304 may be a floating gate type memory cell including a floating gate transistor, or a charge trapping type memory cell including a charge trapping transistor.

In some examples, each memory cell 304 may be a single-level cell (SLC) having two possible memory states and thus may store one bit of data. For example, the SLC may include a 0th state and a 1st state, wherein a threshold voltage distribution of the 0th state may correspond to a first voltage range and a threshold voltage distribution of the 1st state may correspond to a second voltage range. The 0th state is an erase state, and the 1st state is a programmed state. In some examples, each memory cell 304 is a Multi-Level Cell (MLC) capable of storing more than a single bit of data in more than four memory states. For example, an MLC may store two bits of data per cell, three bits of data per cell (also known as a Triple-Level Cell (TLC)), or four bits of data per cell (also known as a Quad-Level Cell (QLC)). Each MLC may be programmed to assume a voltage range of possible threshold voltage distributions. In one example, if each MLC stores two bits of data, the MLC may have a 0th state “11”, a 1st state “10”, a 2nd state “00”, and a 3rd state “01”, wherein threshold voltage distributions of the 0th state, the 1st state, the 2nd state, and the 3rd state correspond to the first, second, third, and fourth voltage ranges, respectively. The 0th state is an erase state, and the 1st state, the 2nd state and the 3rd state are all programmed states. Similarly, a TLC may include an erase state and 7 programmed states; a QLC may include an erase state and 15 programmed states.

As shown in FIG. 4, each memory string 306 may include a source select transistor (SST) 308 at its source terminal and a drain select transistor (DST) 310 at its drain terminal. The source select transistor 308 and the drain select transistor 310 may be configured to activate selected memory strings 306 (columns of the array) during read and program operations. In some examples, the sources of the memory strings 306 in the same memory block 302 are coupled by the same source line (SL) 316 (e.g., a common SL). In other words, in some examples, all the memory strings 306 in the same memory block 302 have an array common source (ACS). In some examples, the drain of the drain select transistor 310 of each memory string 306 is coupled to a corresponding bit line (BL) 318, and data may be read or written via an output bus (not illustrated in FIG. 4) from the bit line 318. In some examples, each memory string 306 is configured to be selected or deselected by applying a select voltage (e.g., higher than a threshold voltage of the drain select transistor 310) or a deselect voltage (e.g., 0V) to the respective drain select transistor 310 via one or more drain selective lines (DSL) 314 and/or by applying a select voltage (e.g., higher than a threshold voltage of the source select transistor 308) or a deselect voltage (e.g., 0V) to the respective source select transistor 308 via one or more source selective lines (SSL) 312.

As shown in FIG. 4, the memory string 306 may be organized into a plurality of memory blocks 302, each of the memory blocks 302 may have a source line 316 (e.g., a common SL coupled to ground). In some examples, each memory block 302 is a basic data unit for performing an erase operation, e.g., all memory cells 304 on the same memory block 302 are erased at the same time. To erase the memory cells 304 in a selected memory block, the source line 316 coupled to the selected memory block and unselected memory blocks in the same plane as the selected memory block may be biased with an erase voltage Vers (e.g., a high positive voltage (e.g., 20 V or higher)). It should be understood that in some examples, an erase operation may be performed at a half memory block level, at a quarter memory block level, or at a level having any suitable number of memory blocks or any suitable fraction of memory blocks. The memory cells 304 of the adjacent memory string 306 may be coupled by a word line 320 (WL), and the word line 320 selects which row of the memory cells 304 is affected by the read and program operations.

It should be noted that, for the SLC, each memory cell may store one bit of information, so that information stored in one layer of memory cells a(for example, one physical page)t the physical level corresponds to information of one logical page. For the MLC, each memory cell may store two bits of information, so that information stored in one layer of memory cells (for example, one physical page)at the physical level corresponds to information of two logical pages. For TLC, each memory cell may store three bits of information, so that information stored in one layer of memory cells (for example, one physical page) at the physical level corresponds to information of three logical pages. For the QLC, each memory cell may store four bits of information, so that information stored in one layer of memory cells (for example, one physical page) at the physical level corresponds to information of four logical pages.

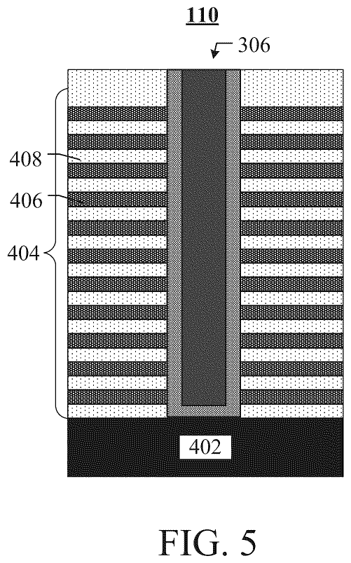

Referring to FIG. 5, which is a schematic cross-sectional view illustrating a memory cell array including memory strings according to an example of the present disclosure. As shown in FIG. 5, a memory string 306 may extend vertically through a memory stack 404 above a substrate 402. The substrate 402 may include silicon (e.g., monocrystalline silicon), silicon germanium (SiGe), gallium arsenide (GaAs), germanium (Ge), Silicon-On-Insulator (SOI), Ge-On-insulator (GOI), or any other suitable material.

The memory stack 404 may include alternating gate conductive layers 406 and gate dielectric layers 408. The number of pairs of the gate conductive layers 406 and the gate dielectric layers 408 in the memory stack 404 may determine the number of memory cells 304 in a memory cell array 110. The gate conductive layer 406 may include a conductive material including, but not limited to, tungsten (W), cobalt (Co), copper (Cu), aluminum (Al), polysilicon, doped silicon, silicide, or any combination thereof. In some examples, each gate conductive layer 406 includes a metal layer, such as a tungsten layer. In some examples, each gate conductive layer 406 includes a doped polysilicon layer. Each gate conductive layer 406 may include a control gate surrounding the memory cell 304 and may laterally extend as a drain selective line 314 at the top of the memory stack 404, as a source selective line 312 at the bottom of the memory stack 404, or as a word line 320 between the drain selective line 314 and the source selective line 312.

As shown in FIG. 5, the memory string 306 includes a channel structure vertically extending through the memory stack 404. In some examples, the channel structure includes a channel hole filled with semiconductor material(s) (e.g., as a semiconductor channel) and dielectric material(s) (e.g., as a memory film). In some examples, the semiconductor channel includes silicon, e.g., polysilicon. In some examples, the memory film is a composite dielectric layer including a tunneling layer, a storage layer (also referred to as a “charge trapping/storage layer”), and a blocking layer. The channel structure may have a cylindrical shape (e.g., a pillar shape). According to some examples, the semiconductor channel, the tunneling layer, the storage layer, and the barrier layer are arranged radially in this order from a center of the pillar toward an outer surface of the pillar. The tunneling layer may include silicon oxide, silicon oxynitride, or any combination thereof. The memory layer may include silicon nitride, silicon oxynitride, or any combination thereof. The barrier layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

According to some examples, a well (e.g., a P-well and/or N-well) may be formed in the substrate 402, and a source end of the memory string 306 contacts with the well. For example, a source line may be coupled to the well to apply an erase voltage to the well (e.g., the source of the memory string) during an erase operation. In some examples, the memory string 306 further includes a channel plug at a drain end of the memory string 306. It is understood that although not illustrated in FIG. 5, additional components of the memory cell array 110 may be formed, including but not limited to a gate line slit/source contact, local contact, interconnect layer, etc.

Referring back to FIG. 4, the peripheral circuit 112 may be coupled to the memory cell array 110 through the bit line 318, the word line 320, the source line 316, the source selective line 312, and the drain selective line 314. The peripheral circuit 112 may include any suitable analog, digital, and mixed signal circuit for facilitating operation of the memory cell array 110 by applying and sensing voltage and/or current signals to and from each target memory cell 304 via the bit lines 318, the word lines 320, the source lines 316, the source selective lines 312, and the drain selective lines 314. The peripheral circuit 112 may include various types of peripheral circuit formed using metal oxide semiconductor (MOS) technology.

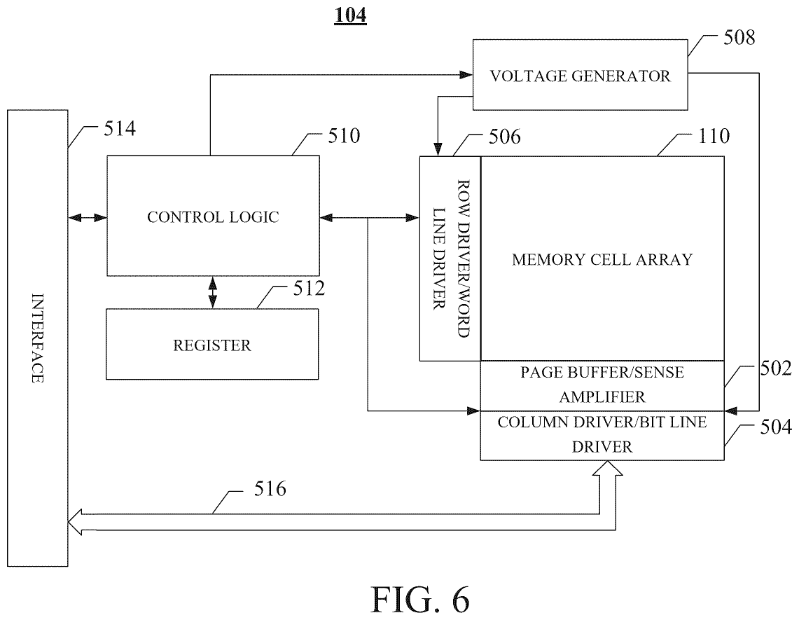

Referring to FIG. 6, which is a block diagram illustrating a memory device including a peripheral circuit according to an example of the present disclosure. As shown in FIG. 6, the peripheral circuit includes a page buffer/sense amplifier 502, a column driver/bit line driver 504, a row driver/word line driver 506, a voltage generator 508, a control logic 510, a register 512, an interface (I/F) 514, and a data bus 516. It should be understood that, in some examples, additional peripheral circuits not illustrated in FIG. 6 may also be included.

The page buffer/sense amplifier 502 may be configured to read data from and program (write) data to the memory cell array 110 according to control signals from the control logic 510. In another example, the page buffer/sense amplifier 502 may perform a program verify operation to ensure that data has been correctly programmed into the memory cell 304 coupled to the selected word line 320. In yet another example, the page buffer/sense amplifier 502 can also sense a low power signal from the bit line 318 representing a data bit stored in the memory cell 304 and amplify a small voltage swing to a recognizable logic level in a read operation. The column driver/bit line driver 504 may be configured to be controlled by the control logic 510 and select one or more memory strings 306 by applying a bit line voltage generated from the voltage generator 508.

The row driver/word line driver 506 may be configured to be controlled by the control logic 510 and select/deselect the memory block 302 of the memory cell array 110 and select/deselect the word line 320 of the memory block 302. The row driver/word line driver 506 may also be configured to drive the word line 320 using a word line voltage generated from the voltage generator 508. In some examples, the row driver/word line driver 506 can also select/deselect and drive the source selective line 312 and the drain selective line 314. As described in detail below, the row driver/word line driver 506 is configured to perform an erase operation on the memory cells 304 coupled to the selected word line(s) 320. The voltage generator 508 may be configured to be controlled by the control logic 510 and generate the word line voltage (e.g., a read voltage, a program voltage, a pass voltage, a local voltage, a verify voltage, etc.), the bit line voltage, and the source line voltage to be supplied to the memory cell array 110.

The control logic 510 may be coupled to each of the peripheral circuits described above and configured to control the operation of each peripheral circuit. The register 512 may be coupled to the control logic 510 and include a status register, a command register, and an address register for storing status information, command operation codes (OP codes), and command addresses for controlling operations of each peripheral circuit. The interface 514 may be coupled to the control logic 510 and act as a control buffer to buffer and relay control commands received from a host (not illustrated in FIG. 6) to the control logic 510, and to buffer and relay status information received from the control logic 510 to the host. The interface 514 may also be coupled to the column driver/bit line driver 504 via the data bus 516 and act as a data input/output (I/O) interface and data buffer to buffer and relay data to or from the memory cell array 110.

The basic principle of a three-dimensional NAND memory device is that carriers (electrons or holes) inject a certain amount of charge into a memory cell across a charge barrier to complete a data writing process, and then the stored data can be read according to a threshold voltage when the memory cell is turned on. Therefore, to read correct data, an error correction algorithm with a strong error correction capability and high efficiency is usually introduced during data reading.

However, as the usage time increases, the charges stored in the memory cell will change with the increase in usage time, repeated read operations, cross temperatures, etc., thereby affecting the correctness of data reading. When the threshold voltage shifts significantly upward or downward, when using an original read voltage to read data from the memory cell, there is a high possibility of read errors. Also, when the read errors are beyond the error correction capability, it may also cause data read failures in the memory cell, resulting in an uncorrectable error correction code (UECC) in a system product.

When the controller controls the memory device to perform a read operation, a FW default read operation is first performed on a memory cell corresponding to a physical address. A read retry operation is performed after the FW default read operation fails, and a Soft Decode operation is performed after the read retry operation fails. A Redundant Array of Independent Disk (RAID) operation is performed after the soft decode fails, and the read operation stops after the RAID operation fails, and the read operation fails due to the inability to correct errors, and the controller sends a Read Fail signal to the host. The read retry operation and the FW default read operation may be applied to hard decode.

Generally, the read retry operation may be performed by querying a retry table provided by the manufacturer in some examples. The essence of the read retry operation is an error correction mechanism. The retry table can provide a reference voltage for reading data. The retry table is queried to try to read respective memory cells again with a read voltage deviating from a normal threshold voltage, in combination with an error correction algorithm to perform error correction, in order to try to read data correctly. Once the read error data is corrected, querying of the retry table is stopped. If the read error data cannot be corrected, then keep querying the retry table until the entire retry table is traversed.

The approach of the above read retry operation needs to query the retry table one item by one item, which will inevitably increase the number of trial and consume a long time. In addition, the retry table provided by the manufacturer is only a reference value in some specific environments, whereas a real-life usage scenario is various, so the retry table provided by the manufacturer cannot cover all the scenarios. As such, the data may not be corrected after traversing the retry table, resulting in a waste of time that could be used for processing commands. In conclusion, the approach of repeatedly polling the read retry table to perform the read retry operation consumes a long time, and affects response time of subsequent commands, thereby affecting performance of the device.

In some other examples, if testing a valley voltage trial and error by using the retry table fails, a valley voltage prediction function may be further used. The valley voltage prediction process is usually time-consuming, and requires multiple iterations to find the valley voltage. This may be because the point selection in the valley voltage prediction process is prone to errors, resulting in additional iterations and reduced data recovery efficiency.

According to one or more of the above technical problems, examples of the present disclosure provide a memory system, an operation method thereof, and a controller.

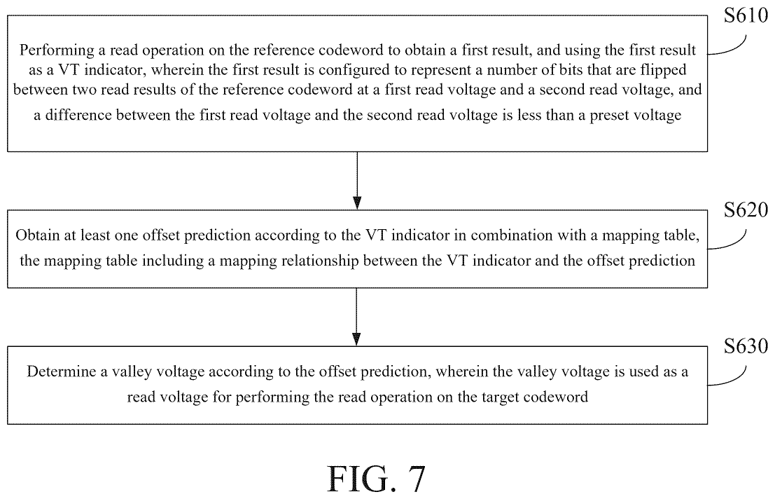

Referring back to FIG. 1 and FIG. 4, in a first aspect, an example of the present disclosure provides a memory system, the memory system 102 includes: at least one memory device 104, and a controller 106 coupled to the memory device 104 and configured to control the memory device 104, wherein the memory device 104 includes a memory cell array 110 and a peripheral circuit 112 coupled to the memory cell array 110, the memory cell array 110 includes a plurality of memory cells 304, and a preset number of memory cells 304 in the plurality of memory cells 304 form a codeword. Referring to FIG. 7, which is a schematic diagram of an implementation process of the memory system configured to perform an operation method provided in an example of the present disclosure. As shown in FIG. 7, the memory system 102 is configured to perform the following operations: in operation S610, the peripheral circuit 112 is configured to: perform a read operation on a reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage; in operation S620, the controller 106 is configured to obtain at least one offset prediction according to the VT indicator in combination with a mapping table, the mapping table including a mapping relationship between the VT indicator and the offset prediction; and in operation S630, the controller 106 is configured to determine a valley voltage according to the offset prediction, the valley voltage is used as a read voltage for performing the read operation on a target codeword.

Herein, the structure of the memory system 102 may refer to related descriptions in FIG. 1, and details are not described herein again.

In some examples, the memory device 104 includes: the memory cell array 110, the memory cell array 110 including a plurality of memory blocks 302; and a plurality of word lines 320 coupled to the memory block 302, with each word line 320 coupled to a plurality of memory cells 304 in the memory block 302. All memory cells 304 coupled by one word line 320 form a physical page. A preset number of memory cells 304 form a code word (CW). A physical page may include one or more codewords.

In some examples, a number of memory cells included in one codeword is the same as a number of memory cells included in one encoding or decoding during error correction encoding or decoding. In some examples, the number of memory cells included in one codeword may be less than or equal to a number of the memory cells coupled by one physical page, for example, the number of the memory cells included in one codeword is ¼ of the number of the memory cells coupled by one physical page. In some other examples, the codeword may include a number of memory cells ranging from 2⁴ to 2¹². For example, the codeword may include 2⁴, 2⁸, or 2¹² memory cells.

In some examples, a certain codeword may be determined as the reference codeword, and the number of the memory cells included in one codeword may be less than or equal to the number of the memory cells coupled by one physical page. In other words, when the number of the memory cells included in one codeword is the same as the number of the memory cells coupled by one physical page, a certain word line may be determined as a reference word line, a read operation is performed on the reference word line to obtain a first result, which is used as a VT indicator.

In general, different memory systems may select codewords of different sizes to meet their performance, reliability, and storage requirements. Memory cells (e.g., MLC, TLC, or QLC) in different types of memory devices may store different numbers of bits. It may be understood that the codeword may include a plurality of memory cells, and the number of the memory cells included in the codeword may be adjusted according to an actual situation.

It should be noted that in practice, the codeword may have some extra reserved space for management and error correction, so the number of the memory cells actually required may slightly exceed the above calculation result.

In the example of the present disclosure, in the operation S610, the peripheral circuit 112 is configured to perform the read operation on the reference codeword to obtain the first result, which is used as the VT indicator. Herein, the first result is configured to represent a number of bits that are flipped between the two read results of the reference codeword to which the read operation is to be performed, at the first read voltage and the second read voltage, and a difference between the first read voltage and the second read voltage is less than the preset voltage.

The following describes a meaning of the first result and a method of obtaining the first result.

In some examples, in a process of performing a read operation on the memory device, data of one physical page is read in one read operation. When a number of memory cells included in one codeword may be less than a number of the memory cells coupled by one physical page, the codeword is a basic unit to which the operation of obtaining the first result can be performed, but the case of multiple codewords is not excluded. For example, the first result corresponding to at least one reference codeword at the reference read voltage may be obtained. For example, one physical page may correspond to four codewords, and a page buffer hardware operation may count the respective fail bit count (FBC) of the four codewords at one time, and then add the FBC of the four codewords to get the FBC of one physical page, and the subsequent calculation may use value obtained by the addition. It may be understood that the first result herein may be based on FBC data of one physical page, and one physical page may correspond to a plurality of reference codewords.

In some examples, the memory cell array 110 includes a memory cell 304 having M memory bits, the M memory bits respectively corresponding to M pages, and the M-bit memory cell 304 reads its M-bit data through Q read voltages (e.g., Q read levels), wherein M and Q are both integers greater than or equal to 2, and Q=2^{M}−1.

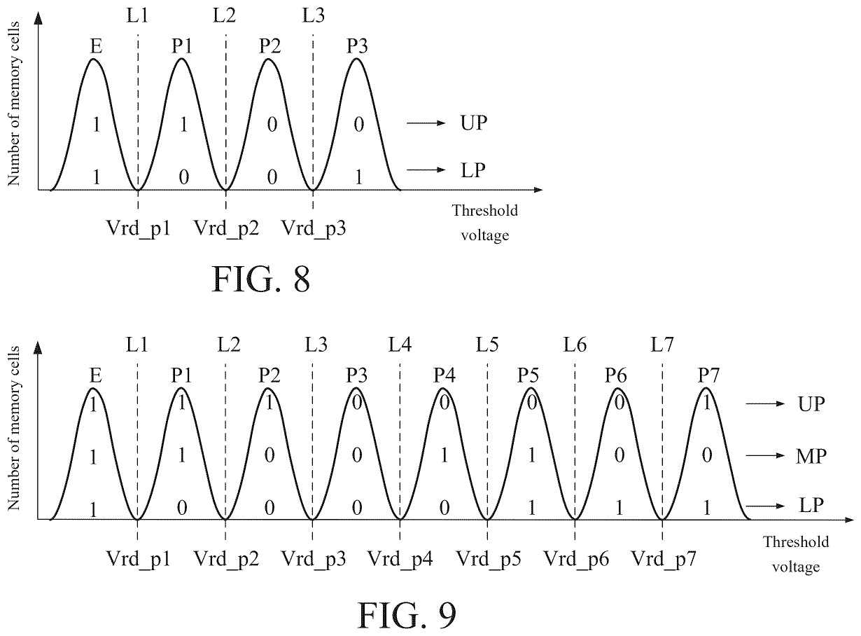

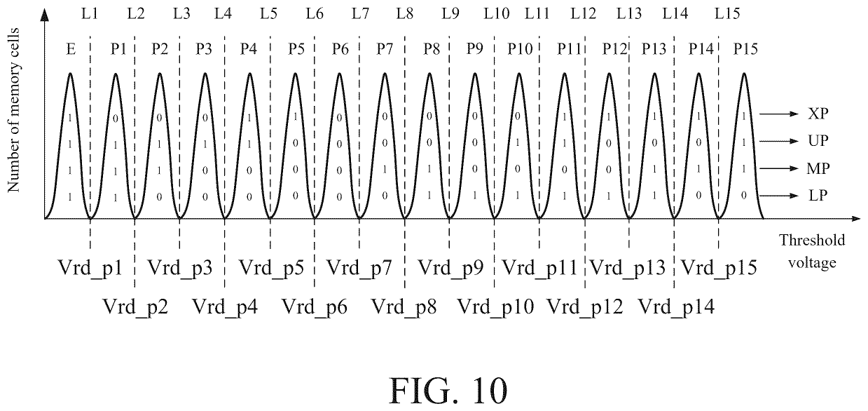

Referring to FIG. 8 to FIG. 10, FIG. 8, FIG. 9, and FIG. 10 are threshold voltage distribution diagrams corresponding to memory cells with two, three, and four memory bits provided by examples of the present disclosure. Illustrative descriptions are provided below with reference to FIG. 8 to FIG. 10.

For example, when the memory cell has two memory bits, the corresponding memory states include the 0th state to the 3rd state. Referring to FIG. 8, among the above four states, the 0th state is the erase state E, and the first state, the second state and the third state are the first programming state P1, the second programming state P2 and the third programming state P3, respectively. The binary data corresponding to the foregoing four states are 11, 10, 00, and 01, respectively. Correspondingly, the memory device includes two pages: a lower page (LP) and an upper page (UP). Herein, the two memory bits corresponding to the four states are respectively stored in the lower page and the upper page.

Taking the memory cell shown in FIG. 8 as an example, the two-bit stored data of a two-bit memory cell is read through three read levels (a first read level L1, a second read level L2 and a third read level L3 shown in FIG. 8), and the three read levels respectively correspond to three read voltages, for example, a first read voltage Vrd_p1, a second read voltage Vrd_p2 and a third read voltage Vrd_p3. As shown in FIG. 8, the binary data corresponding to the lower page is 1001, and the corresponding first read voltage Vrd_p1 and third read voltage Vrd_p3 are required to read the lower page. The binary data corresponding to the upper page is 1100, and the corresponding second read voltage Vrd_p2 is required to read the upper page.

For example, when the memory cell has three memory bits, the corresponding memory states include the 0th state to the 7th state. Referring to FIG. 9, among the above eight states, the 0th state is the erase state E, and the 1st state, the 2nd state, the 3rd state, . . . , and the 7th state are the first program state P1, the second program state P2, the third program state P3, . . . , and the seventh program state P7, respectively. Binary data corresponding to the foregoing eight states are 111, 110, 100, 000, 010, 011, 001, and 101, respectively. Correspondingly, the memory device includes three pages: a lower page, a middle page (MP), and an upper page. Herein, the three memory bits corresponding to the eight states are respectively stored in the lower page, the middle page, and the upper page.

Taking the memory cell shown in FIG. 9 as an example, three-bit stored data of the three-bit memory cell is read through seven read levels (the first read level L1, the second read level L2, the third read level L3, the fourth read level L4, the fifth read level L5, the sixth read level L6 and the seventh read level L7 shown in FIG. 9), and the seven read levels respectively correspond to seven read voltages, for example, the first read voltage Vrd_p1, the second read voltage Vrd_p2, the third read voltage Vrd_p3, the fourth read voltage Vrd_p4, the fifth read voltage Vrd_p5, the sixth read voltage Vrd_p6 and the seventh read voltage Vrd_p7. The lower page corresponds to two read voltages, the middle page corresponds to three read voltages, and the upper page corresponds to two read voltages. As shown in FIG. 9, the binary data corresponding to the lower page are 10000111, and the corresponding first read voltage Vrd_p1 and fifth read voltage Vrd_p5 are required to read the lower page. The binary data corresponding to the middle page are 11001100, and the corresponding second read voltage Vrd_p2, fourth read voltage Vrd_p4 and sixth read voltage Vrd_p6 are required for reading the middle page. The binary data corresponding to the upper page are 11100001, and the corresponding third read voltage Vrd_p3 and seventh read voltage Vrd_p7 are required to read the upper page.

For example, when the memory cell has four memory bits, the corresponding memory states include the 0th state to the 15th state. Referring to FIG. 10, among the foregoing sixteen states, the 0th state is the erase state E, and the 1st state, the 2nd state, the 3rd state, . . . , and the 15th state are the first program state P1, the second program state P2, the third program state P3, . . . , and the fifteenth program state P15, respectively. Binary data corresponding to the foregoing sixteen states is 1111, 0111, 0110, 0100, 1100, 1000, 0000, 0010, 0011, 0001, 0101, 1101, 1001, 1011, 1010, and 1110, respectively. Correspondingly, the memory device includes four pages: a lower page, a middle page, an upper page, and an extra page (XP). Herein, the four memory bits corresponding to the sixteen states are respectively stored in the lower page, the middle page, the upper page, and the extra page.

Taking the memory cell illustrated in FIG. 10 as an example, the four-bit stored data of the four-bit memory cell is read through fifteen read levels (the first read level L1, the second read level L2, the third read level L3, the fourth read level L4, the fifth read level L5, the sixth read level L6, the seventh read level L7, the eighth read level L8, the ninth read level L9, the tenth read level L10, the eleventh read level L11, the twelfth read level L12, the thirteenth read level L13, the fourteenth read level L14, and the fifteenth read level L15 shown in FIG. 10), and the fifteen read levels respectively correspond to fifteen read voltages, for example, the first read voltage Vrd_p1, the second read voltage Vrd_p2, the third read voltage Vrd_p3, the fourth read voltage Vrd_p4, the fifth read voltage Vrd_p5, the sixth read voltage Vrd_p6, the seventh read voltage Vrd_p7, the eighth read voltage Vrd_p8, the ninth read voltage Vrd_p9, the tenth read voltage Vrd_p10, the eleventh read voltage Vrd_p11, the twelfth read voltage Vrd_p12, the thirteenth read voltage Vrd_p13, the fourteenth read voltage Vrd_p14, and the fifteenth read voltage Vrd_p15. The lower page corresponds to three read voltages, the middle page corresponds to four read voltages, the upper page corresponds to four read voltages, and the extra page corresponds to four read voltages. As shown in FIG. 10, the binary data corresponding to the lower page is 1100000011111100, and the corresponding second read voltage Vrd_p2, eighth read voltage Vrd_p8 and fourteenth read voltage Vrd_p14 are required to read the lower page. The binary data corresponding to the middle page is 1110000110000111, and the corresponding third read voltage Vrd_p3, the seventh read voltage Vrd_p7, the ninth read voltage Vrd_p9 and the thirteenth read voltage Vrd_p13 are required to read the middle page. The binary data corresponding to the upper page is 1111100000110001, and the corresponding fifth read voltage Vrd_p5, tenth read voltage Vrd_p10, twelfth read voltage Vrd_p12 and fifteenth read voltage Vrd_p15 are required to read the upper page. The binary data corresponding to the extra page is 1000110000011111, and the corresponding first read voltage Vrd_p1, fourth read voltage Vrd_p4, sixth read voltage Vrd_p6 and eleventh read voltage Vrd_p11 are required to read the extra page.

The lower page is usually closest to the source/drain, so the valley voltage of each of the multi-level read voltages corresponding to the lower page is determined at first, which achieves the fastest access speed, the shortest response time, which can ensure balanced performance and endurance in the data access process. It should be noted that the approach of determining the valley voltage of each of the multi-level read voltages corresponding to the lower page at first is merely an example, and is not used to limit a determination order of valley voltages of each of the multi-level read voltages corresponding to at least some pages in the example of this application.

Herein, both the first read voltage and the second read voltage are both general concepts, and a difference between the first read voltage and the second read voltage is less than a preset voltage. In the first result corresponding to the reference codeword, the reference read voltage of the reference read level is the first read voltage, and the second read voltage may be obtained by adjusting the first read voltage. The first read voltage may be determined based on a default read voltage of the reference read level. For example, the first read voltage may be the default read voltage of the reference read level, and at this time, a difference between the first read voltage and the default read voltage of the reference read level is 0; alternatively, the first read voltage may be obtained after adjusting the default read voltage of the reference read level, and the first read voltage may be greater than the default read voltage of the reference read level or the first read voltage may be less than the default read voltage of the reference read level. It should be noted that the reference read level is selected from one of a plurality of read levels, and the default read voltage of each of the plurality of read levels is a read voltage when the threshold voltage has not shifted. In some examples, the second read voltage may be greater than the first read voltage, and a range of the difference between the first read voltage and the second read voltage is set to 5 mV to 20 mV. For example, a difference between the first read voltage and the second read voltage may be 5 mV, 10 mV, 15 mV, or 20 mV. In some other examples, the second read voltage may be less than the first read voltage, and a range of a difference between the first read voltage and the second read voltage is set to −5 mV to −20 mV, for example, the difference between the first read voltage and the second read voltage may be −5 mV, −10 mV, −15 mV, or −20 mV.

In some examples, the peripheral circuit 112 is configured to: read the stored data of the reference codeword at the first read voltage to obtain a second result; read the stored data of the reference codeword at the second read voltage to obtain a third result; perform a logical operation on the second result and the third result to obtain a fourth result; and count a number of bits in the fourth result representing the flipping of the third result compared to the second result to obtain the first result.

In some examples, the peripheral circuit 112 includes: a first latch, a second latch, and a third latch; the first latch is configured to store the second result; the second latch is configured to store the third result; and the third latch is configured to store the fourth result.

Here, the first read voltage and the second read voltage are associated with each other, for example, the second read voltage is obtained by adjusting the first read voltage. Based on this, the difference between the first read voltage and the second read voltage is a step size. In some examples, the step size ranges from 5 mV to 20 mV, for example, the step size may be 5 mV, 10 mV, 15 mV, or 20 mV. The preset voltage is related to the step size, and may be a voltage slightly greater than the step size. In some examples, the range of the preset voltage is set to 6 mV to 21 mV, for example, the preset voltage may be 6 mV, 11 mV, 16 mV, or 21 mV. In some other examples, a range of the preset voltage is set to −6 mV to −21 mV, for example, the preset voltage may be −6 mV, −11 mV, −16 mV, or −21 mV.

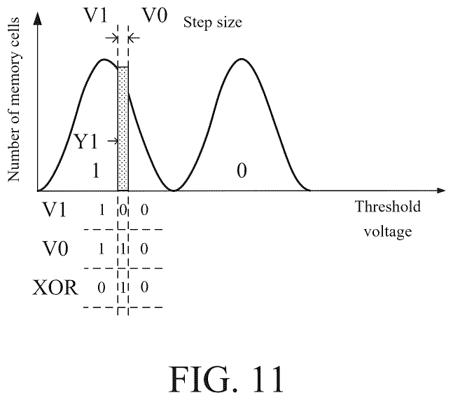

Referring to FIG. 11, which is a threshold voltage distribution diagram corresponding to a memory cell when obtaining a first result as provided by an example of the present disclosure. In the examples of the present disclosure, the first result corresponding to a certain voltage (for example, the first read voltage V0 shown in FIG. 11) may be understood as: after adjusting a certain voltage, there is a voltage difference between the certain voltage and the adjusted certain voltage (for example, the second read voltage V1 shown in FIG. 11), and a number of bits that are flipped between two read results of a preset number of memory cells at the certain voltage and at the adjusted certain voltage, may be taken as the first result corresponding to the certain voltage, wherein the preset number of memory cells may form a codeword.

In an example of the present disclosure, the peripheral circuit 112 is configured to: perform a read operation on the reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage.

In some examples, the peripheral circuit 112 is configured to: obtain, in a single level read mode (SLR), a first result corresponding to the reference codeword at a reference read voltage (for example, a default read voltage) of a reference read level, and use the first result as a VT indicator, wherein the default read voltage is a read voltage when a threshold voltage has not shifted.

In some examples, the memory device 104 is configured to: enter a single level read mode in response to a mode setting command, and obtain, in the single level read mode, the first result corresponding to the reference codeword at the reference read voltage (e.g., the default read voltage) of the reference read level.

The normal read mode and the single level read mode will be explained below with reference to FIG. 9 and FIG. 11, taking TLC as an example.

Before introducing the single level read mode, the normal reading mode is explained first. Performing the normal read operation on the TLC includes sequentially performing a read operation on the lower page, the middle page, and the upper page. Here, in the read operation on the lower page, the read operations of the first read voltage Vrd_p1 and the fifth read voltage Vrd_p5 may be sequentially performed. When the read operation of the first read voltage Vrd_p1 is performed, the memory cell with a threshold voltage less than the first read voltage Vrd_p1 is turned on, and the memory cell with a threshold voltage greater than the first read voltage Vrd_p1 is turned off. Therefore, data “1” may be read from memory cells having threshold voltages less than the first read voltage Vrd_p1, and data “0” may be read from memory cells having threshold voltages greater than the first read voltage Vrd_p1.

Since the first read voltage Vrd_p1 is the minimum read voltage among the read voltages for identifying the lower page data, the data “1” read from the memory cells whose threshold voltages are less than the first read voltage Vrd_p1 are deterministic data, for example, the data “1” may be read from the memory cells corresponding to the erase state E and having threshold voltages less than the first read voltage Vrd_p1. Since the read operation on the lower page is completed by further performing the read operation of the fifth read voltage Vrd_p5, the data “0” read from the memory cells whose threshold voltages are greater than the fifth read voltage Vrd_p5 are not deterministic data.

When the read operation of the fifth read voltage Vrd_p5 is performed, a ground voltage may be applied to the bit line corresponding to the memory cells having the deterministic data and in the erase state E, and a precharge voltage may be applied to the remaining bit lines. When the read operation of the fifth read voltage Vrd_p5 is performed, data “1” may be read from the memory cells having the first to fourth program states P1 to P4, and data “0” may be read from the memory cells having the fifth to seventh program states P5 to P7. According to the algorithm of the lower page read operation, the data read using the fifth read voltage Vrd_p5 may be flipped and stored in a page buffer. Therefore, the data read from the memory cells corresponding to the first to fourth program states P1 to P4 and having threshold voltages less than the fifth read voltage Vrd_p5 may be determined as “0”, and the data read from the memory cells corresponding to the fifth to seventh program states P5 to P7 and having threshold voltages greater than the fifth read voltage Vrd_p5 may be determined as “1”.

Here, at the end of the read operation on the lower page, the read operation on the middle page may be performed. In the read operation on the middle page, read operations of the second read voltage Vrd_p2, the fourth read voltage Vrd_p4, and the sixth read voltage Vrd_p6 may be sequentially performed. When the read operation of the second read voltage Vrd_p2 is performed, data “1” may be read from memory cells whose threshold voltages are less than the second read voltage Vrd_p2, and data “0” may be read from memory cells whose threshold voltages are greater than the second read voltage Vrd_p2.

Since the second read voltage Vrd_p2 is the minimum read voltage among the read voltages for identifying the middle page data, the data “1” read from the memory cells whose threshold voltages are less than the second read voltage Vrd_p2 are the deterministic data, for example, the data “1” may be read from the memory cells corresponding to the erase state E and the first program state P1 and having threshold voltages less than the second read voltage Vrd_p2. Since the read operation on the middle page is completed by further performing the read operations of the fourth read voltage Vrd_p4 and the sixth read voltage Vrd_p6, the data “0” read from the memory cells whose threshold voltages are greater than the fourth read voltage Vrd_p4 are not deterministic data.

When the read operation of the fourth read voltage Vrd_p4 is performed, a ground voltage may be applied to the bit lines corresponding to the memory cells having the deterministic data and in the erase state E and the first program state P1, and a precharge voltage may be applied to the remaining bit lines. When the read operation of the fourth read voltage Vrd_p4 is performed, data “1” may be read from the memory cells having the second program state P2 and the third program state P3, and data “0” may be read from the memory cells having the fourth program state P4 to the seventh program state P7. According to the algorithm of the middle page read operation, the data read using the fourth read voltage Vrd_p4 may be flipped and stored in the page buffer. Therefore, the data read from the memory cells corresponding to the second program state P2 and the third program state P3 and having threshold voltages less than the fourth read voltage Vrd_p4 may be determined as “0”, and the data read from the memory cells corresponding to the fourth to seventh program states P4-P7 and having threshold voltages greater than the fourth read voltage Vrd_p4 may be determined as “1”.

Since the read operation on the lower page is completed by further performing the read operation of the sixth read voltage Vrd_p6, the data “1” read from the memory cells whose threshold voltages are greater than the sixth read voltage Vrd_p6 are not deterministic data.

When the read operation of the sixth read voltage Vrd_p6 is performed, a ground voltage may be applied to the bit lines corresponding to the memory cells having the deterministic data and in the erase state E and the first to third program states P1 to P3, and the precharge voltage may be applied to the remaining bit lines. When the read operation of the sixth read voltage Vrd_p6 is performed, data “1” may be read from memory cells corresponding to the fourth and fifth program states P4 and P5 and having threshold voltages less than the sixth read voltage Vrd_p6, and data “0” may be read from memory cells having the sixth and seventh program states P6 and P7.

Here, at the end of the read operation on the middle page, a read operation on the upper page may be performed. In the read operation on the upper page, read operations of the third read voltage Vrd_p3 and the seventh read voltage Vrd_p7 may be sequentially performed. When the read operation of the third read voltage Vrd_p3 is performed, data “1” may be read from memory cells whose threshold voltages are less than the third read voltage Vrd_p3, and data “0” may be read from memory cells whose threshold voltages are greater than the third read voltage Vrd_p3.

Since the third read voltage Vrd_p3 is the minimum read voltage among the read voltages for identifying the upper page data, the data “1” read from the memory cells whose threshold voltages are less than the third read voltage Vrd_p3 are deterministic data, for example, the data “1” may be read from the memory cells corresponding to the erase state E, the first program state P1 and the second program state P2 and having threshold voltages less than the third read voltage Vrd_p3. Since the read operation on the upper page is completed by further performing a read operation of the seventh read voltage Vrd_p7, the data “0” read from the memory cells whose threshold voltages are greater than the seventh read voltage Vrd_p7 are not deterministic data.

When the read operation of the seventh read voltage Vrd_p7 is performed, a ground voltage may be applied to the bit lines corresponding to the memory cells having the deterministic data and in the erase state E, the first program state P1 and the second program state P2, and the precharge voltage may be applied to the remaining bit lines. When the read operation of the seventh read voltage Vrd_p7 is performed, data “1” may be read from the memory cells having the third to sixth program states P3 to P6, and data “0” may be read from the memory cells having the seventh program state P7. According to the algorithm of the upper page read operation, data read using the seventh read voltage Vrd_p7 may be flipped and stored in the page buffer. Thus, data read from memory cells corresponding to the third to sixth program states P3 to P6 and having threshold voltages less than the seventh read voltage Vrd_p7 may be determined as “0”, and data read from memory cells corresponding to the seventh program state P7 and having threshold voltages greater than the seventh read voltage Vrd_p7 may be determined as “1”.

It should be noted that, since the TLC includes eight states, the normal read mode is performed on the TLC to distinguish the eight states, which requires a group of read voltages, which include seven read voltages. Only after all read voltages in the group of read voltages are used, a read result can be obtained, wherein the read result refers to the specific data stored in a certain memory cell that is obtained by reading. For example, a three-bit stored data stored in a certain memory cell may be read as “101”.

However, the single level read mode refers to performing a read operation using one of the plurality of read voltages included in the group of read voltages, and obtaining a number of the memory cells whose threshold voltages are greater than or equal to the read voltage and a number of the memory cells whose threshold voltages are less than the read voltage, as a read result. The data from the memory cells whose threshold voltages are less than the read voltage may be determined as “1”, and the data from the memory cells whose threshold voltages are greater than or equal to the read voltage may be determined as “0”. Of course, “1” and “0” here do not represent the data actually stored in the memory cells, instead, they are classified only according to the magnitude relationship between the read voltage and the threshold voltages of the memory cells, in which the memory cells with threshold voltages less than the read voltage are taken as a first type, and the data stored in the first type of memory cells are regarded as “1”; and the memory cells with threshold voltages greater than or equal to the read voltage are taken as a second type, and the data stored in the second type of memory cells are regarded as “0”.

In some examples, the stored data of the reference codeword is read at the first read voltage to obtain a second result; and the second result is stored in a first latch of the memory device. For example, referring to FIG. 11, the stored data of the reference codeword is read at the first read voltage V0 to obtain the second result. In an example, the memory cells whose threshold voltages are less than the first read voltage V0 are marked as “1”, the memory cells whose threshold voltages are greater than the first read voltage V0 are marked as “0”, thereby the second result is obtained. The second result is stored in the first latch of the memory device.

Then, the first read voltage is adjusted to obtain a second read voltage, and the stored data of the reference codeword is read at the second read voltage. In an example, referring to FIG. 11, the first read voltage V0 is adjusted, and the stored data of the reference codeword is read at the second read voltage V1 after adjustment, to obtain a third result. In an example, the memory cells whose threshold voltages are less than the second read voltage V1 are marked as “1”, and the memory cells whose threshold voltage are greater than the second read voltage V1 are marked as “0”, thereby the third result is obtained. The third result is stored in a second latch of the memory device.

Next, a logical operation is performed on the second result and the third result to obtain fourth result; and the fourth result is stored in a third latch of the memory device. In an example, referring to FIG. 11, an XOR operation is performed on the second result and the third result to obtain the fourth result; and the fourth result is stored in the third latch of the memory device.

It should be noted that the XOR operation is one of the basic logic operations. In binary, if two binary numbers at the same position are the same, the result is “0”, and if two binary numbers at the same position are different, the result is “1” (for example, 0 when the same, and 1 when different).

Then, the number of bits in the fourth result representing the flipping of the third result compared to the second result is counted to obtain the first result. For example, referring to FIG. 11, “1” in the fourth result represents the number of the memory cells whose threshold voltages are different between the first read voltage V0 and the second read voltage V1. In other words, “1” in the fourth result indicates the number of the bits that are flipped between the two read results of the reference codeword at the first read voltage V0 and the second read voltage V1, and the number of “1” is denoted as the first result corresponding to the first read voltage V0.

In some examples, a read level with a moderate threshold voltage shift among the Q read levels may be selected as a reference read level, for example, the Q read levels include the reference read level, for example, the reference read level is selected from the Q read levels. A read level with a moderate threshold voltage shift is selected as the reference read level, then the VT indicator at the reference read level is more representative, which is more beneficial to improving the accuracy of subsequently determining the valley voltage.

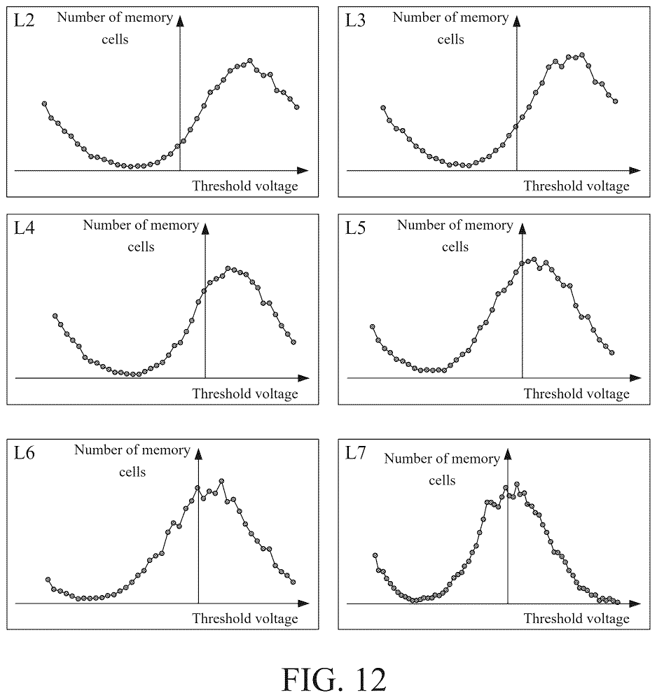

Referring to FIG. 12, which is threshold voltage distribution diagrams corresponding to memory cells at different read levels provided by an example of the present disclosure. As shown in FIG. 12, the horizontal axis is the threshold voltage, the vertical axis is the number of memory cells. The position of threshold voltage DAC=0 may be understood as the position of the default read voltage, and the default read voltage may be the read voltage when the threshold voltage of the memory cell has not shifted, for example, the read voltage corresponding when the memory cell is just written, which has a corresponding offset of 0. The position of the threshold voltage DAC=−10 mV represents the default read voltage at its read level minus 10 mV, e.g., shifted downward by 10 mV from the default read voltage at this read level; the position of the threshold voltage DAC=−20 mV represents the default read voltage at its read level minus 20 mV, e.g., shifted downward by 20 mV from the default read voltage at this read level. The position of the threshold voltage DAC=10 mV represents the default read voltage at its read level plus 10 mV, e.g., shifted upward by 10 mV from the default read voltage at this read level; the position of the threshold voltage DAC=20 mV represents the default read voltage at its read level plus 20 mV, e.g., shifted upward by 20 mV from the default read voltage at this read level.

For example, in the threshold voltage distribution diagram corresponding to the memory cell under the second read level L2, the difference between the valley voltage and DAC=0 may represent the degree of shift of the threshold voltage. From the second read level L2 to the seventh read level L7 in sequence, the degree to which the threshold voltage shifts downward increases in sequence. For example, the degree of shift of the threshold voltage of the memory cell at the seventh read level L7 is the largest. Under the condition of a high temperature bake, the threshold voltages of the memory cells at the fifth read level L5, the sixth read level L6 and the seventh read level L7 may be shifted excessively, resulting in that the position of the default read voltage is already over-hill. The degree of shift of the threshold voltage of the memory cell at the fourth read level L4 is moderate, which is more suitable for reflecting the degree of shift of the threshold voltage. Thus, the fourth read level L4 can be selected as the reference read level in the TLC.

It should be noted that the above description is made only by taking the degree of shift o the threshold voltage of the memory cell at respect read level in a certain application scenario as an example, which does not mean that only the fourth read level L4 can be selected as the reference read level in TLC. In other application scenarios, the TLC may also select the third read level L3 or the fifth read level L5 as the reference read level. In the present disclosure, which read level is selected among the plurality of read levels as the reference read level is not particularly limited, and it needs to be determined in combination with application scenarios.

In the example of the present disclosure, in the operation S610, the first result (which may also be referred to as FBC) of the reference codeword at the reference read level is used as a VT indicator, which is configured to represent the degree of shift of the threshold voltage of the memory cell at the target read level. The mapping table includes at least a mapping relationship between the VT indicator and a offset prediction. The mapping table may be stored in the controller 106, and in the operation S620, the mapping table is looked up according to the VT indicator to obtain at least one offset prediction.

In some examples, the controller 106 is configured to: obtain, according to the VT indicator, a VT indicator grade corresponding to the VT indicator, wherein the VT indicator grade is configured to represent one or more continuously arranged VT indicators.

As described above, the VT indicator refers to the first result, for example, the FBC. For example, The numerical value of the VT indicator varies, and the VT indicator may be 211, 107, 86 or 53, etc. If the mapping table is established by using the VT indicator as one of the factors, the storage capacity occupied by the mapping table may be large. Therefore, grouping or segmentation may be performed on the VT indicators to obtain the VT indicator grade, which is configured to represent one or more continuously arranged VT indicators. When each VT indicator grade is configured to represent one VT indicator, a number of the VT indicator grades is the same as a number of the VT indicators. When each VT indicator grade is configured to represent a plurality of continuously arranged VT indicators, the number of the VT indicator grades is less than the number of the VT indicators, which reduces a storage capacity occupied by the mapping table and facilitates grouping management or segmentation management on data.

For example, each VT indicator grade is configured to represent 10 continuously arranged VT indicators. VT indicator grade 1 may be configured to represent the VT indicators 0 to 9, VT indicator grade 2 may be configured to represent the VT indicators 10 to 19, and so on, VT indicator grade 22 may be configured to represent the VT indicators 210 to 219. In an example, if the VT indicator obtained by performing the operation S610 is 211, then it may be determined that the VT indicator grade is 22. In the present disclosure, the number of continuously arranged VT indicators represented by the VT indicator grade is not particularly limited, and each VT indicator grade may include 2, 5, 8, 10, 15 or 20 continuously arranged VT indicators.

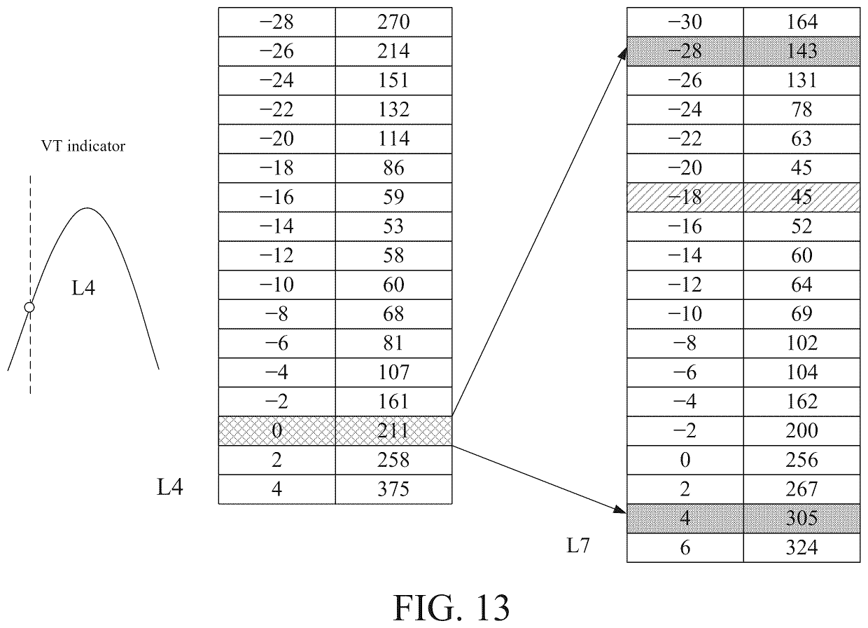

Referring to FIG. 13, which is a schematic diagram of determining a VT indicator grade provided by an example. As shown in FIG. 13, when the reference read level is the fourth read level L4, the first result corresponding to the reference codeword at the default read voltage (for example, DAC=0) of the fourth read level L4 is obtained as 211, then the VT indicator is determined as 211. When the number of the continuously arranged VT indicators represented by the VT indicator grade is 10, the VT indicator grade may be determined as 22 according to the VT indicator being 211.

In some examples, the controller 106 is configured to: obtain at least one offset prediction according to the VT indicator grade and a target read level of a target codeword in combination with the mapping table, wherein the mapping table includes at least a mapping relationship among the VT indicator grade, the target read level, and the offset prediction. The VT indicator grade of the reference codeword is used as the VT indicator grade of the target codeword.

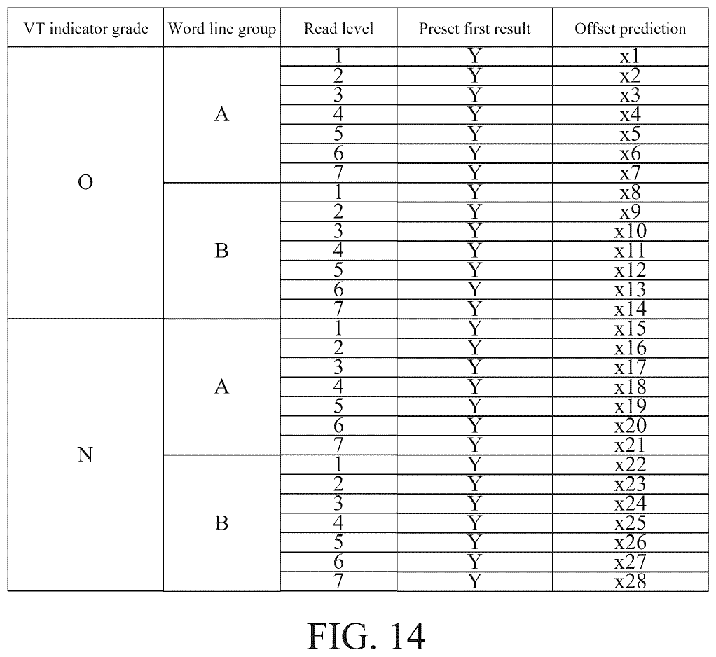

Referring to FIG. 14, which is a schematic diagram of a mapping table provided by an example of the present disclosure. As shown in FIG. 14, the first column is a VT indicator grade, the third column is a target read level, and the fifth column is an offset prediction. The VT indicator grade and the target read level may be respectively used as one of the factors for determining the offset prediction. The mapping table is looked up according to the VT indicator grade (for example, the VT indicator grade N) and the target read level (for example, the target read level L6) that are determined as described above, to obtain at least one offset prediction (for example, when the word line group is A, the offset prediction is x20, or when the word line group is B, the offset prediction is x27).

In some examples, the controller 106 is configured to: obtain a word line group corresponding to the target codeword according to a position of the target codeword in the memory cell array, the word line group representing one or more adjacently disposed word lines.

Here, the positions of different word lines in the memory cell array are different, and therefore, the degree of shift of the threshold voltages of the memory cells coupled to different word lines are different. If the mapping table is established by using the word line as one of the factors, the storage capacitor occupied by the mapping table is large. Therefore, the word lines may be grouped to obtain a word line group, and the word line group is configured to represent one or more adjacently disposed word lines. When each word line group is used to represent one word line, the number of the word line groups is the same as the number of the word lines. When each word line group is used to represent a plurality of adjacently disposed word lines, the number of the word line groups is less than the number of the word lines, which reduces the storage capacity occupied by establishing the mapping table using the word line group is reduced and facilitates group management to the data.

Here, the word lines with the same threshold voltage shift variation may be managed as the same word line group, and the offset predictions at different VT indicator grades and different read levels are managed in the same word line group. In other words, when other conditions are the same, the degree of shift of the threshold voltages in different word line groups may have different variation rules. For example, each word line group is configured to represent 50 adjacent word lines, a word line group 1 may be configured to represent word lines WL1 to WL50, and a word line group 2 may be configured to represent word lines WL51 to WL100. In the present disclosure, it does not have special limitation on the number of adjacent word lines represented by the word line group, and each word line group may include 20, 30, 40 or 50 adjacent word lines.

In some examples, the controller 106 is configured to: obtain at least one offset prediction according to the VT indicator grade, the target read level of the target codeword, and the word line group corresponding to the target codeword in combination with a mapping table, wherein the mapping table includes a mapping relationship among the VT indicator grade, the target read level, the word line group, and the offset prediction. The VT indicator grade of the reference codeword is used as the VT indicator grade of the target codeword.

Referring to FIG. 14, the first column is the VT indicator grade, the second column is the word line group (WL group), the third column is the target read level, and the fifth column is the prediction offset. The VT indicator grade, the word line group, and the target read level may be respectively used as one of factors for determining the offset prediction. The mapping table is looked up according to the VT indicator grade (for example, the VT indicator grade N), the word line group (for example, the word line group A), and the target read level (for example, the target read level L6) that are determined as described above, to obtain at least one offset prediction (for example, x20).

In a first example of the present disclosure, the at least one offset prediction includes two offset predictions, and two preset first results corresponding to the two offset predictions are both within a preset interval; the controller 106 is configured to: obtain two target read voltages according to the two offset predictions; the peripheral circuit 112 is configured to: obtain a first result corresponding to the target codeword at one target read voltage, and obtain a first result corresponding to the target codeword at another target read voltage; and the controller 106 is configured to: obtain the valley voltage according to the two target read voltages and the two first results corresponding to the two target read voltages in combination with a preset function model.

As shown in FIG. 13 and FIG. 14, the mapping table is looked up according to the VT indicator grade (for example, the VT indicator grade N), the word line group (for example, the word line group A), and the target read level (for example, the target read level L7) determined as described above, to obtain at least one offset prediction (for example, x21). The offset prediction x21 may include, for example, DAC=−28 and DAC=4, and when DAC=−28, the preset first result is 143; when DAC=4, the preset first result is 305. According to DAC=−28, DAC=4 and the default read voltage at the target read level, the target read voltage (denoted as x11) corresponding to DAC=−28 and the target read voltage (denoted as x12) corresponding to DAC=4 may be determined; the read operation is performed by using the target read voltage x11 to obtain the first result y11, and the read operation is performed by using the target read voltage x12 to obtain the first result y12; and the actual measured point values (x11, y11) and (x12, y12) obtained by performing the read operation are substituted into the preset function model to obtain the valley voltage. It should be noted that, referring to the preset first result (target raw FBC value) shown in column 4 in FIG. 14, the two preset first results 143 and 305 are both within the preset interval, and the two actual first results y11 and y12 are determined after performing the read operation.

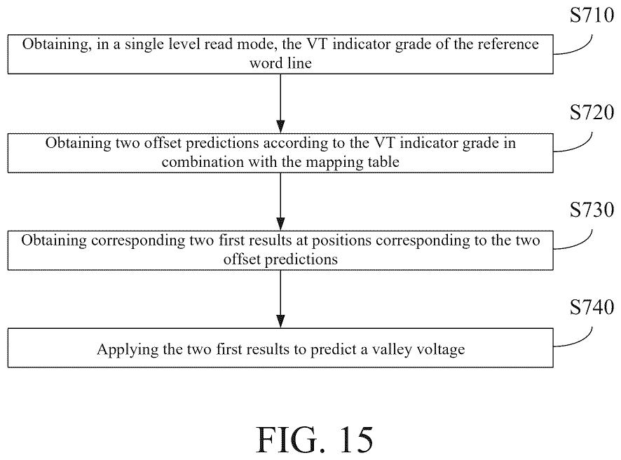

Referring to FIG. 15, which is a schematic flowchart of determining a valley voltage provided by some examples of the present disclosure. As shown in FIG. 15, in operation S710, the VT indicator grade of a reference word line is obtained in the single level read mode; in operation S720, two offset predictions are obtained according to the VT indicator grade in combination with the mapping table; in operation S730, the corresponding two first results are obtained at positions corresponding to the two offset predictions; and in operation S740, the two first results are applied to predict a valley voltage. When one physical page includes one codeword, obtaining the VT indicator grade of the reference codeword is obtaining the VT indicator grade of the reference wordline.

Therefore, in the first example of the present disclosure, the memory device is required perform two read operations, and the valley voltage is calculated according to the actual measured point values (x11, y11) and (x12, y12). It should be noted that, when fitting by using the preset model function, data selection is particularly important. The corresponding preset first result when DAC=−28 is 143, the corresponding preset first result when DAC=4 is 305, and the two preset first results 143 and 305 are both within the preset interval. The calculation using the data within the preset interval can more accurately reflect the valley voltage, which facilitates to improve the accuracy of obtaining the valley voltage by fitting the preset model.

In a second example of the present disclosure, the at least one offset prediction includes one offset prediction; and the controller 106 is configured to obtain the valley voltage according to the one offset prediction.

With reference to FIG. 13 and FIG. 14, the mapping table is looked up according to the VT indicator grade (for example, the VT indicator grade N), the word line group (for example, the word line group A), and the target read level (for example, the target read level L7) that are determined as described above, to obtain at least one offset prediction (for example, x21) and a preset first result. The offset prediction x21 may include, for example, DAC=−18, and when DAC=−18, the preset first result is 45. The valley voltage can be directly determined according to DAC=−18 and the default read voltage at the target read level. It should be noted that the preset first result of 45 belongs to the minimum value in the FBC, for example, the target read voltage corresponding to the preset first result is the valley voltage.

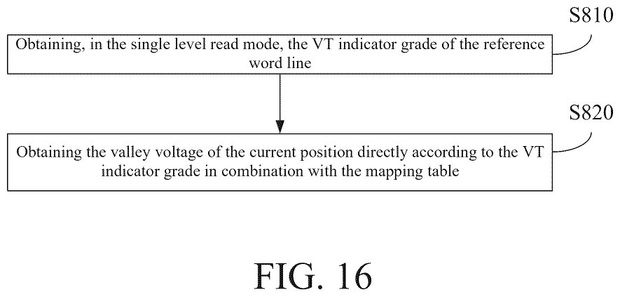

Referring to FIG. 16, which is a schematic flowchart of determining a valley voltage provided by some other examples of the present disclosure. As shown in FIG. 16, in operation S810, a VT indicator grade of a reference word line is obtained in the single level read mode; and in operation S820, the valley voltage at the current position is directly obtained according to the VT indicator grade in combination with the mapping table.

Therefore, in the second example of the present disclosure, there is no need to use the memory device to perform the read operation, and the valley voltage is directly obtained by looking up the mapping table, and the speed of obtaining the valley voltage is faster.

In a third example of the present disclosure, the at least one offset prediction includes two offset predictions, and two preset first results corresponding to the two offset predictions are both within a preset interval; and the controller 106 is configured to: obtain two target read voltages according to the two offset predictions; and obtain the valley voltage according to the two target read voltages and the corresponding two preset first results in combination with a preset function model.

As shown in FIG. 13 and FIG. 14, the mapping table is looked up according to the VT indicator grade (for example, the VT indicator grade N), the word line group (for example, the word line group A), and the target read level (for example, the target read level L7) determined as described above, to obtain at least one offset prediction (for example, x21). The offset prediction x21 may include, for example, DAC=−28 and DAC=4, and when DAC=−28, the preset first result is 143; when DAC=4, the preset first result is 305. According to DAC=−28, DAC=4 and the default read voltage at the target read level, the target read voltage (denoted as x21) corresponding to DAC=−28 and the target read voltage (denoted as x22) corresponding to DAC=4 may be determined; the preset first result corresponding to DAC=−28 is taken as y21, the preset first result corresponding to DAC=4 is taken as y22, and the point values (x21, y21) and (x22, y22) obtained by looking up the table without performing read operation are substituted into the preset function model to obtain the valley voltage. It should be noted that the two preset first results 143 and 305 are both within the preset interval.

Therefore, in the above example, the valley voltage is calculated according to the point values (x21, y21) and (x22, y22) obtained by looking up the table without performing read operation using the memory device, which makes the speed of obtaining the valley voltage faster.

In some examples, the preset function model is related to characteristics of the memory device, and the preset function model may be obtained by fitting a large number of experimental results before the memory device leaves the factory, and stored in the memory device. In an example, the preset function model is encoded into code, and the code is stored into firmware or software of the memory device, or the code may be stored into the controller.

In some examples, a large amount of data is collected through a large amount of experiments before the memory device leaves the factory, and may be preprocessed by removing outliers, sorting, denoising, and the like, and then analyzed, and a preset function model is fitted by using a statistical method, machine learning, or another modeling technology, to describe a relationship between the target read voltage and the first result. In an example, a regression analysis method is used to fit the preset function model by using a large number of collected target read voltages and corresponding first results. In an example, by using a data-driven method such as machine learning or deep learning, a preset function model is established by using a large number of collected target read voltages and the corresponding first results to represent a relationship between the target read voltages and the first results.

In some examples, the preset function model includes a quadratic function model, which includes the following function expression: y=a(x+b)²+c, wherein y is the first result, x is the target read voltage, b is used for representing a prediction parameter, a is the first parameter, and c is the second parameter.

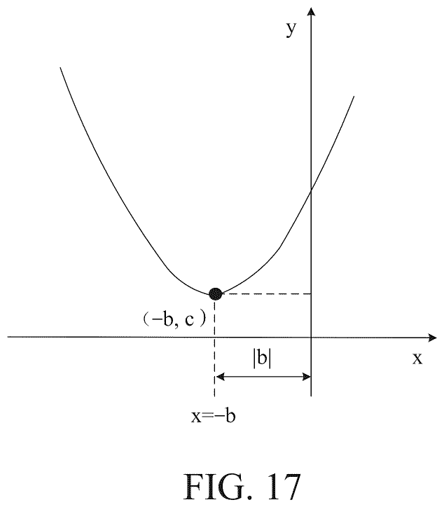

Referring to FIG. 17, which is a schematic diagram of a preset function model provided by some examples of the present disclosure. As shown in FIG. 17, with reference to the function relationship included in the quadratic function model, it can be learned that the extreme value of the curve where the quadratic function model is located is located at the position where the symmetry axis is x=−b, for example, the position where the derivative of the curve where the quadratic function model is located is 0. In an example, when the first parameter a is greater than 0, the corresponding y value (the first result) at x=−b is the minimum value of the curve where the quadratic function model is located, and the coordinate of the extreme point is (−b, c).

In some examples, the first parameter is a variable, and the second parameter is a constant; and the controller 106 is configured to: obtain a prediction parameter according to the two target read voltages and the two first results corresponding to the two target read voltages in combination with the quadratic function model; and use the prediction parameter as the valley voltage. Here, the second parameter may be obtained when fitting the preset function model.

Herein, the second parameter in the function relationship may be optimized by using, but not limited to, a least square method, a gradient descent method, Bayesian optimization, a Newton method, a quasi-Newton method, and the like. The least square method is a parameter estimation method, which estimates parameters by minimizing a sum of squares of residuals between actually collected data and predicted values of the quadratic function model. The gradient descent rule is to use a parameter of the quadratic function model as an optimization target, use a gradient descent method to find a parameter value that minimizes a fitting error of the quadratic function model, calculate a gradient of a loss function with respect to the second parameter, and then update the value of the second parameter in a direction opposite to the gradient until convergence is reached.

In some examples, the value of the prediction parameter is an inverse of b, for example, the prediction parameter represents the horizontal axis corresponding to the minimum value of the curve where the quadratic function model is located. The offset of the symmetry axis (at x=−b) of the curve where the quadratic function model is located relative to the y-axis (at x=0) is −b, for example, the distance between the symmetry axis of the curve where the quadratic function model is located and the y-axis is the absolute value |b|of b.

Here, x=0 may be understood as the position of the default read voltage, and the default read voltage may be the read voltage when the threshold voltage of the memory cell has not shifted. It may be understood that when the offset of the target read voltage relative to the default read voltage (x=0) is −b, the corresponding first result at the target read voltage is the minimum value. It may be understood that the corresponding target read voltage (equivalent to the prediction parameter) when the first result is the minimum value is used as the valley voltage, which makes the read result have a low error rate and high reliability. Here, the read operation is performed on the target codeword, the value of the read voltage may be the valley voltage, and the reliability of the read result is high. Of course, when performing a read operation on the target codeword, the value of the read voltage does not have to be strictly limited to the valley voltage. The valley voltage may be adjusted within a certain range, and the read operation on the target codeword may be performed using the adjusted valley voltage. The error rate of the read result may also meet the usage requirements.

In some examples, the preset interval represents a numerical interval of the first result corresponding to a preset region of the curve where the preset function model is located. The preset interval refers to a numerical interval of the first result corresponding to the experimental data that can accurately reflect the distribution of the actual valley voltage when fitting the preset function model. In other words, the data for obtaining the valley voltage is screened through the preset interval, which is beneficial to improving the accuracy of obtaining the valley voltage.

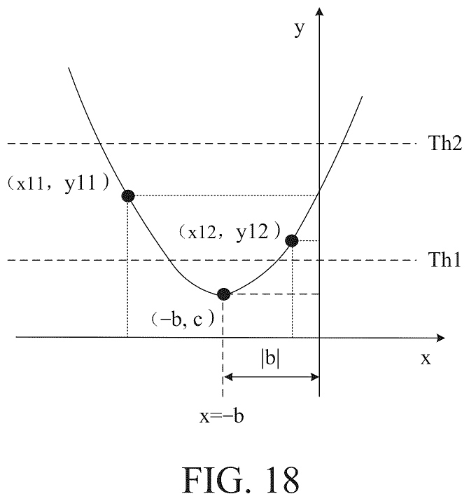

Referring to FIG. 18, which is a schematic diagram of determining a predicted valley voltage according to a preset function model provided by some examples of the present disclosure. As shown in FIG. 18, the preset interval represents a range between a first threshold and a second threshold of a curve where the quadratic function model is located, and the first threshold (Th1) is less than the second threshold (Th2). With reference to FIG. 13, two preset first results corresponding to the two offset predictions DAC=−28 and DAC=4 are both within the preset interval.

In an example, the preset interval ranges from 50 to 100. It should be noted that the range of the preset interval provided in the examples of the present disclosure is only an example, and the range of the preset interval is related to the characteristics of the memory device and should not unduly limit the protection scope of the present disclosure.

It should be noted that, in the examples of the present disclosure, the purpose of performing the read operation on the reference codeword is to obtain the first result as the VT indicator, and this read operation uses the reference read voltage of the reference read level, for example, the first read voltage (for example, the default read voltage of the reference level) and the second read voltage obtained by adjusting the first read voltage. In some examples, the fourth read level L4 may be used as the reference read level. The purpose of performing the read operation on the target codeword is to obtain the target data, and this read operation uses the valley voltage of the target read level determined in the process of looking up the mapping table. The target read level is selected from a plurality of read levels, and when each of the plurality of read levels is used as the target read level, respective corresponding valley voltages can be obtained. In some examples, if the target read level determined in the process of looking up the mapping table is the fifth read level L5, the finally determined valley voltage corresponds to the fifth read level L5; and if the target read level determined in the process of looking up the mapping table is the third read level L3, the finally determined valley voltage corresponds to the third read level L3.

In some examples, the peripheral circuit 112 is configured to: perform a read operation on the target codeword according to the valley voltage to obtain the target data; and the controller 106 is configured to: obtain the target data. Here, performing the read operation according to the valley voltage determined above can improve the accuracy of the read operation.

In the memory system provided by the example of the present disclosure, the memory device is used to perform the read operation on the reference codeword to obtain the VT indicator; the controller is used to obtain at least one offset prediction according to the VT indicator in combination with the mapping table; and the valley voltage is obtained according to the offset prediction. In a first aspect, the shift rule of the voltage curve is used to describe the degree of shift of the threshold voltage by using the VT indicator (or the VT indicator grade), to determine the valley voltage. In this way, the valley voltage prediction can be completed within a range of very few selected points, and the probability of invalid selected points is reduced to 0, for example, the data recovery is quickly completed by using the precisely selected point, which improves the efficiency of obtaining the valley voltage, and avoids the performance degradation of the memory device during data recover. For example, in the first example and the third example of the present disclosure, two offset predictions are obtained at each read level by looking up the mapping table, for example, two valid point values are selected; in the second example of the present disclosure, one offset prediction is obtained at each read level by looking up the mapping table, for example, one valid point value is selected. In a second aspect, the method of obtaining the valley voltage may be compatible with various conditions such as an open block, a close block, an inner block, an edge block, an beginning of life (BOL), an end of life (EOL), and a data retention degree, to reduce complexity of the data recovery module. In a third aspect, the valley voltage at any position in the entire memory may be obtained by using the VT indicator (or the VT indicator grade) of the reference codeword in combination with the mapping table. In a fourth aspect, the foregoing method of obtaining a valley voltage may be applicable to an MLC, TLC, or QLC memory system.

In a second aspect, an example of the present disclosure further provides a controller, as shown by referring back to FIG. 1, the controller 106 is coupled to at least one memory device 104, the memory device 104 includes a memory cell array 110 and a peripheral circuit 112 coupled to the memory cell array 110, the memory cell array 110 includes a plurality of memory cells, and a preset number of memory cells in the plurality of memory cells form a codeword.

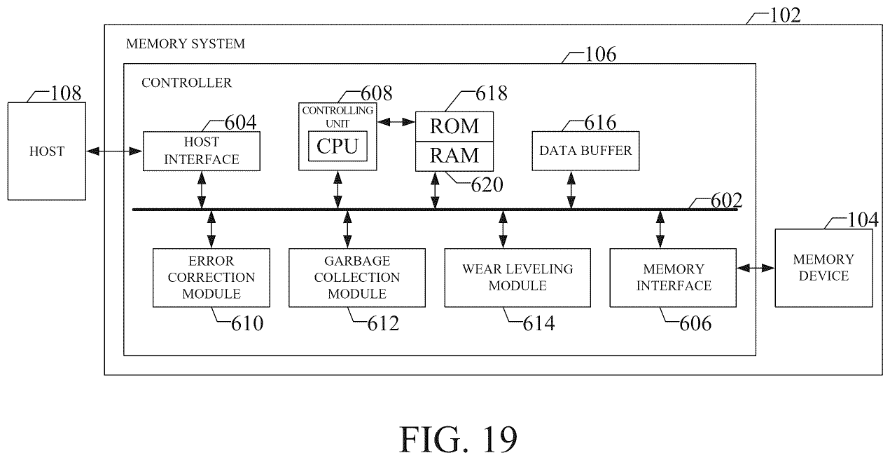

Referring to FIG. 19, which is a block diagram of a controller provided by some examples of the present disclosure. As shown in FIG. 19, the memory system 102 is coupled to the host 108 and performs various feedbacks in response to instructions from the host 108. The memory system 102 may include a controller 106 and a memory device 104, wherein the controller 106 is configured to control the memory device 104 to perform operations such as read, write and erase, and the controller 106 and the memory device 104 may also be coupled in any suitable manner.

The controller 106 may include a host interface 604, a memory interface 606, a control unit 608, a read-only memory (ROM) 618, a random access memory (RAM) 620, an error correction module 610, a garbage collection module 612, a wear leveling module 614, a data buffer 616, and a bus 602. The host interface 604 is a connection interface connecting the host 108 and the controller 106, and the host interface 604 allows the host 108 and the controller 106 to communicate according to a specific protocol, send read and write requests, and perform other operations. The memory interface 606 is a connection interface between the controller 106 and the memory device 104, and the memory interface 606 is configured to implement data transmission between the controller 106 and the memory device 104. The control unit 608 is configured to control the memory system 102 as a whole, and the operations performed by the controller 106 are mainly performed and completed by the control unit 608 here. In some examples, the control unit 608 is, for example, a CPU, a microprocessor (MCU), or the like. The read-only memory 618 typically includes firmware or firmware program code of the controller 106 for initializing and operating the components of the controller 106, and the random access memory 620 is typically configured for buffering data. The error correction module 610 may further include an encoding unit and a decoding unit; in which the encoding unit is configured to encode data to be stored to obtain check data, and the decoding unit is configured to decode the check data to detect and correct possible error data during data transmission.

The garbage collection module 612 is configured to, after the storage space of the memory device 104 reaches a certain threshold, read out valid data on some memory blocks, rewrite the valid data, and then mark these memory blocks to obtain new spare memory blocks. General implementation of garbage collection may be divided into three operations: selecting a source memory block with less valid data; finding out the valid data from the source memory block; and writing the valid data to a target memory block. In this case, all data in the source memory block becomes invalid data, and the source memory block is marked and may be used as a new backup memory block. The wear leveling module 614 is configured to keep the wear (erase count) of each memory block in the memory system balanced through data statistics and algorithms. A general implementation of wear leveling may be divided into two operations: selecting a source memory block where cold data is located; and reading valid data on the source memory block and writing the valid data to a memory block with a relatively large erase count. At this time, the valid data in the source memory block becomes invalid data and is marked. The data buffer 616 is configured to buffer data.

In some examples, the controller 106 (in an example, the control unit 608) is configured to: perform a read operation on the reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage; obtain at least one offset prediction according to the VT indicator in combination with a mapping table, wherein the mapping table includes a mapping relationship between the VT indicator and the offset prediction; and determine a valley voltage according to the offset prediction, wherein the valley voltage is used as a read voltage when the read operation is performed on the target codeword.

In some examples, the memory cell has M memory bits, the M memory bits correspond to (2^{M}−1) read levels, the (2^{M}−1) read levels include a reference read level, and M is an integer greater than or equal to 2; and the controller 106 is configured to: obtain, in the single level read mode, a first result corresponding to the reference codeword at a default read voltage of the reference read level, and use the first result as a VT indicator, wherein the default read voltage is a read voltage when the threshold voltage has not shifted.

In some examples, the controller 106 is configured to: obtain a VT indicator grade corresponding to the VT indicator according to the VT indicator, the VT indicator grade being configured for representing one or more continuously arranged VT indicators.

In some examples, the controller 106 is configured to: obtain at least one offset prediction according to the VT indicator grade and the target read level of the target codeword in combination with a mapping table, wherein the mapping table includes a mapping relationship among the VT indicator grade, the target read level, and the offset prediction.

In some examples, the controller 106 is configured to: obtain a word line group corresponding to the target codeword according to a position of the target codeword in the memory cell array, the word line group being configured for representing one or more adjacent word lines.

In some examples, the controller 106 is configured to: obtain at least one offset prediction according to the VT indicator grade, the target read level of the target codeword, and the word line group corresponding to the target codeword in combination with a mapping table, wherein the mapping table includes a mapping relationship between the VT indicator grade, the target read level, the word line group, and the offset prediction.

In some examples, the at least one offset prediction includes two offset predictions, and two preset first results corresponding to the two offset predictions are both within a preset interval; and the controller 106 is configured to: obtain two target read voltages according to the two offset predictions; obtain a first result corresponding to the target codeword at one target read voltage, and obtain a first result corresponding to the target codeword at the other target read voltage; and obtain the valley voltage according to the two target read voltages and the two first results corresponding to the two target read voltages in combination with a preset function model.

In some examples, the preset function model includes a quadratic function model, and the quadratic function model includes the following function expression: y=a(x+b)²+c, wherein y is the first result, x is the target read voltage, b is configured to represent a prediction parameter, a is a first parameter, and c is a second parameter.

In some examples, the first parameter is a variable, and the second parameter is a constant; and the controller 106 is configured to: obtain the prediction parameter according to the two target read voltages and the two first results corresponding to the two target read voltages in combination with the quadratic function model; and use the prediction parameter as the valley voltage.

In some examples, the at least one offset prediction includes one offset prediction; and the controller 106 is configured to obtain the valley voltage according to the one offset prediction.

In some examples, the at least one offset prediction includes two offset predictions, and two preset first results corresponding to the two offset predictions are both within a preset interval; and the controller 106 is configured to: obtain two target read voltages according to the two offset predictions; and obtain the valley voltage according to the two target read voltages and the two preset first results corresponding to the two target read voltages in combination with the preset function model.

In some examples, the controller 106 is configured to perform the read operation on the target codeword according to the valley voltage to obtain the target data.

In the controller provided by the example of the present disclosure, the controller is configured to perform the read operation on the reference codeword to obtain the VT indicator; obtain at least one offset prediction according to the VT indicator in combination with the mapping table; and obtain the valley voltage according to the offset prediction. In a first aspect, a shift rule of the voltage curve is used to describe the degree of shift of the threshold voltage by using the VT indicator (or the VT indicator grade), to determine the valley voltage. In this way, the valley voltage prediction can be completed within a range of very few selected points, and the probability of invalid selected points is reduced to 0, for example, the data recovery may be quickly completed, which improves the efficiency of obtaining the valley voltage, and avoids the performance degradation of the memory device during data recover. In a second aspect, the method of obtaining the valley voltage can be compatible with various conditions, to reduce complexity of the data recovery module. In a third aspect, the valley voltage at any position in the entire memory may be obtained by using the VT indicator (or the VT indicator grade) of the reference codeword in combination with the mapping table. In a fourth aspect, the foregoing method of obtaining the valley voltage may be applicable to an MLC, TLC, or QLC memory system.

In a third aspect, an example of the present disclosure provides an operation method of a memory system. Referring back to FIG. 1, the memory system 102 includes: at least one memory device 104 and a controller 106 coupled to the memory device 104 and configured to control the memory device 104, wherein the memory device 104 includes a memory cell array 110 and a peripheral circuit 112 coupled to the memory cell array 110, the memory cell array 110 includes a plurality of memory cells, and a preset number of memory cells in the plurality of memory cells form a codeword; the operation method includes: performing, by the peripheral circuit, a read operation on a reference codeword to obtain a first result, and using the first result as a VT indicator, wherein the first result is configured to represent a number of bits that are flipped between two read results of the reference codeword at a first read voltage and a second read voltage, and a difference between the first read voltage and the second read voltage is less than a preset voltage; obtaining, by the controller, at least one offset prediction according to the VT indicator in combination with a mapping table, wherein the mapping table includes a mapping relationship between the VT indicator and the offset prediction; and determining a valley voltage according to the offset prediction, wherein the valley voltage is used as a read voltage for performing the read operation on the target codeword.

In some examples, the memory cell has M memory bits, the M memory bits correspond to (2^{M}−1) read levels, the (2^{M}−1) read levels include a reference read level, and M is an integer greater than or equal to 2; and the performing, by the peripheral circuit 112, the read operation on the reference codeword to obtain the first result, and using the first result as the VT indicator includes: obtaining, by the peripheral circuit 112 in a single level read mode, the first result corresponding to the reference codeword at a default read voltage of the reference read level, and using the first result as the VT indicator, wherein the default read voltage is a read voltage when a threshold voltage has not shifted.

In some examples, the operation method further includes: obtaining, by the controller 106, according to the VT indicator, a VT indicator grade corresponding to the VT indicator, wherein the VT indicator grade is configured to represent one or more continuously arranged VT indicators.

In some examples, the obtaining, by the controller 106, at least one offset prediction according to the VT indicator in combination with the mapping table, includes: obtaining, by the controller 106, the at least one offset prediction according to the VT indicator grade and the target read level of the target codeword in combination with the mapping table, wherein the mapping table includes a mapping relationship between the VT indicator grade, the target read level, and the offset prediction.

In some examples, the operation method further includes: obtaining, by the controller 106, a word line group corresponding to the target codeword according to a position of the target codeword in the memory cell array, wherein the word line group is configured to represent one or more adjacently disposed word lines.

In some examples, the obtaining, by the controller 106, at least one offset prediction according to the VT indicator in combination with the mapping table includes: obtaining, by the controller 106, the at least one offset prediction according to the VT indicator grade, the target read level of the target codeword, and the word line group corresponding to the target codeword in combination with the mapping table, wherein the mapping table includes a mapping relationship between the VT indicator grade, the target read level, the word line group, and the offset prediction.

In some examples, the at least one offset prediction includes two offset predictions, and two preset first results corresponding to the two offset predictions are both within a preset interval; and the determining a valley voltage according to the offset prediction includes: obtaining, by the controller 106, two target read voltages according to the two offset predictions; obtaining, by the peripheral circuit 112, a first result corresponding to the target codeword at one target read voltage, and a first result corresponding to the target codeword at another target read voltage; and obtaining, by the controller 106, the valley voltage according to the two target read voltages and the two first results corresponding to the two target read voltages in combination with a preset function model.

In some examples, the preset function model includes a quadratic function model, and the quadratic function model includes the following function expression: y=a(x+b)²+c, wherein y is the first result, x is the target read voltage, b is configured to represent a prediction parameter, a is a first parameter, and c is a second parameter.

In some examples, the first parameter is a variable, and the second parameter is a constant; and the obtaining, by the controller, the valley voltage according to the two target read voltages and the two first results corresponding to the two target read voltages in combination with the preset function model includes: obtaining the prediction parameter according to the two target read voltages and the two first results corresponding to the two target read voltages in combination with the quadratic function model; and using the prediction parameter as the valley voltage.

In some examples, the at least one offset prediction includes one offset prediction; and the determining the valley voltage according to the offset prediction includes: obtaining the valley voltage according to the offset prediction.

In some examples, the at least one offset prediction includes two offset predictions, and two preset first results corresponding to the two offset predictions are both within a preset interval; and the determining the valley voltage according to the offset prediction includes: obtaining two target read voltages according to the two offset predictions; and obtaining the valley voltage according to the two target read voltages and the two preset first results corresponding to the two target read voltages in combination with the preset function model.

In some examples, the operation method further includes: performing, by the peripheral circuit, the read operation on the target codeword according to the valley voltage to obtain target data; and obtaining, by the controller, the target data.

In some examples, the performing, by the peripheral circuit 112, the read operation on the reference codeword to obtain the first result includes: reading stored data of the reference codeword at the first read voltage to obtain a second result; reading the stored data of the reference codeword at the second read voltage to obtain a third result; performing a logical operation on the second result and the third result to obtain a fourth result; and count a number of bits in the fourth result representing the flipping of the third result compared to the second result to obtain the first result.

An example of the present disclosure further provides a storage medium having executable instructions stored thereon, and when the executable instructions are executed, operations of the operation method in the above examples of the present disclosure can be implemented.

In some examples, the storage medium may be a ferromagnetic random access memory (FRAM), a ROM, a programmable read-only memory (PROM), an erasable programmable read-only memory (EPROM), an electrically erasable programmable read-only memory (EEPROM), a flash memory, a magnetic surface memory, an optical disc, or Compact Disc Read-Only Memory (CD-ROM), or may be various apparatus including one or any combination of the foregoing memory devices.

In some examples, the executable instructions may be written in a form of a program, software, a software module, a script, or code in any form of programming language (including a compiled or interpreted language, or a declarative or procedural language), and may be deployed in any form, including being deployed as an independent program or being deployed as a module, a component, a subroutine, or other units suitable for use in a computing environment.

In an example, the executable instructions may, but do not necessarily, correspond to a file in a file system, and may be stored in part of a file that stores other programs or other data, for example, stored in one or more scripts in a hypertext markup language (HTML) document, stored in a single file dedicated to the program in question, or stored in the plurality of collaborative files (for example, stored in files of one or more modules, subprograms, or code parts).

As an example, the executable instructions may be deployed to be executed on one electronic apparatus, or executed on a plurality of electronic apparatuses located at one place, or executed on a plurality of electronic apparatuses distributed at a plurality of places and interconnected through a communication network.

It should be understood that “one example” or “an example” mentioned throughout the specification means that particular features, structures, or characteristics related to the example are included in at least one example of the present disclosure. Therefore, “in one example” or “in an example” appearing throughout the specification does not necessarily refer to the same example. Furthermore, the particular features, structures, or characteristics may be combined in any suitable manner in one or more examples. It should be understood that, in various examples of the present disclosure, the sequence numbers of the above processes do not mean an execution sequence, and the execution sequence of respective processes should be determined by its function and internal logic, which should not impose any limitation on the implementation process of the examples of the present disclosure. The sequence numbers of the above examples of the present disclosure are only for description, and do not represent the advantages or disadvantages of the examples.

The above descriptions are only preferred examples of the present disclosure, and are not intended to limit the protection scope of the present disclosure. All equivalent structural changes made by using the description and the drawings of the present disclosure under the inventive concept of the present disclosure, or the directly/indirectly application in other related technical fields are included in the protection scope of the present disclosure.

What is claimed is:

1. A memory system, comprising:
at least one memory device, and
a controller coupled to the memory device and configured to control the memory device, wherein:
the memory device comprises a memory cell array and a peripheral circuit coupled to the memory cell array, the memory cell array comprises a plurality of memory cells, and a preset number of memory cells in the plurality of memory cells form a codeword;
the peripheral circuit is configured to: perform a read operation on a reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage; and
the controller is configured to:
obtain at least one offset prediction according to the VT indicator in combination with a mapping table, wherein the mapping table comprises a mapping relationship between the VT indicator and the offset prediction; and
determine a valley voltage according to the offset prediction, wherein the valley voltage is used as a read voltage for performing the read operation on a target codeword.

2. The memory system of claim 1, wherein each memory cell has M memory bits, the M memory bits correspond to (2^{M}−1) read levels, the (2^{M}−1) read levels comprise a reference read level, and M is an integer greater than or equal to 2; and the peripheral circuit is configured to:
obtain, in a single level read mode, a first result corresponding to the reference codeword at a default read voltage of the reference read level, and use the first result as the VT indicator, wherein the default read voltage is a read voltage when a threshold voltage has not shifted.

3. The memory system of claim 1, wherein the controller is configured to:
obtain a VT indicator grade corresponding to the VT indicator according to the VT indicator, wherein the VT indicator grade is configured to represent one or more continuously arranged VT indicators; and
obtain at least one offset prediction according to the VT indicator grade and a target read level of the target codeword in combination with the mapping table, wherein the mapping table comprises a mapping relationship among the VT indicator grade, the target read level, and the offset prediction.

4. The memory system of claim 3, wherein the controller is configured to:
obtain a word line group corresponding to the target codeword according to a position of the target codeword in the memory cell array, wherein the word line group is configured to represent one or more adjacently disposed word lines.

5. The memory system of claim 4, wherein the controller is configured to:
obtain at least one offset prediction according to the VT indicator grade, a target read level of the target codeword, and the word line group corresponding to the target codeword in combination with the mapping table, wherein the mapping table comprises a mapping relationship among the VT indicator grade, the target read level, the word line group, and the offset prediction.

6. The memory system of claim 5, wherein the at least one offset prediction comprises two offset predictions, and two preset first results corresponding to the two offset predictions are both within a preset interval; and the controller is configured to obtain two target read voltages according to the two offset predictions;
the peripheral circuit is configured to obtain a first result corresponding to the target codeword at one of the target read voltages, and obtain a first result corresponding to the target codeword at another one of the target read voltages; and
the controller is configured to obtain the valley voltage according to the two target read voltages and two first results corresponding to the two target read voltages in combination with a preset function model.

7. The memory system of claim 6, wherein the preset function model comprises a quadratic function model, and the quadratic function model comprises a following function expression:
y=a(x+b)²+c, wherein y is the first result, x is the target read voltage, b is configured to represent a prediction parameter, a is a first parameter, and c is a second parameter.

8. The memory system of claim 7, wherein the first parameter is a variable, the second parameter is a constant, and the controller is configured to:
obtain the prediction parameter according to the two target read voltages and the two first results corresponding to the two target read voltages in combination with the quadratic function model; and
use the prediction parameter as the valley voltage.

9. The memory system of claim 5, wherein the at least one offset prediction comprises one offset prediction; and the controller is configured to:
obtain the valley voltage according to the one offset prediction.

10. The memory system of claim 5, wherein the at least one offset prediction comprises two offset predictions, and two preset first results corresponding to the two offset predictions are both within a preset interval; and the controller is configured to:
obtain two target read voltages according to the two offset predictions; and
obtain the valley voltage according to the two target read voltages and the two preset first results corresponding to the two target read voltages in combination with a preset function model.

11. The memory system of claim 1, wherein the peripheral circuit is configured to perform a read operation on the target codeword according to the valley voltage to obtain target data; and
the controller is configured to obtain the target data.

12. The memory system of claim 1, wherein the peripheral circuit is configured to:
read stored data of the reference codeword at the first read voltage to obtain a second result; and
read the stored data of the reference codeword at the second read voltage to obtain a third result;
perform a logical operation on the second result and the third result to obtain a fourth result; and
count a number of bits in the fourth result representing the flipping of the third result compared to the second result, to obtain the first result.

13. A controller, wherein the controller is coupled to at least one memory device, the memory device comprises a memory cell array and a peripheral circuit coupled to the memory cell array, the memory cell array comprises a plurality of memory cells, and a preset number of memory cells in the plurality of memory cells form a codeword; and the controller is configured to:
perform a read operation on a reference codeword to obtain a first result, and use the first result as a VT indicator, wherein the first result is configured to represent a number of bits that are flipped between two read results of the reference codeword at a first read voltage and a second read voltage, and a difference between the first read voltage and the second read voltage is less than a preset voltage;
obtain at least one offset prediction according to the VT indicator in combination with a mapping table, wherein the mapping table comprises a mapping relationship between the VT indicator and the offset prediction; and
determine a valley voltage according to the offset prediction, wherein the valley voltage is used as a read voltage for performing the read operation on a target codeword.

14. The controller of claim 13, wherein each memory cell has M memory bits, the M memory bits correspond to (2^{M}−1) read levels, the (2^{M}−1) read levels comprise a reference read level, and M is an integer greater than or equal to 2; and the controller is configured to:
obtain, in a single level read mode, a first result corresponding to the reference codeword at a default read voltage of the reference read level, and use the first result as the VT indicator, wherein the default read voltage is a read voltage when a threshold voltage has not shifted;
obtain a VT indicator grade corresponding to the VT indicator according to the VT indicator, wherein the VT indicator grade is configured to represent one or more continuously arranged VT indicators; and
obtain at least one offset prediction according to the VT indicator grade and a target read level of the target codeword in combination with the mapping table, wherein the mapping table comprises a mapping relationship among the VT indicator grade, the target read level, and the offset prediction.

15. The controller of claim 14, wherein the controller is configured to:
obtain a word line group corresponding to the target codeword according to a position of the target codeword in the memory cell array, wherein the word line group is configured to represent one or more adjacently disposed word lines.

16. The controller of claim 15, wherein the controller is configured to:
obtain at least one offset prediction according to the VT indicator grade, a target read level of the target codeword, and the word line group corresponding to the target codeword in combination with the mapping table, wherein the mapping table comprises a mapping relationship among the VT indicator grade, the target read level, the word line group, and the offset prediction.

17. The controller of claim 16, wherein the at least one offset prediction comprises two offset predictions, and two preset first results corresponding to the two offset predictions are both within a preset interval; and the controller is configured to:
obtain two target read voltages according to the two offset predictions;
obtain a first result corresponding to the target codeword at one of the target read voltages, and obtain a first result corresponding to the target codeword at another one of the target read voltages; and
obtain the valley voltage according to the two target read voltages and two first results corresponding to the two target read voltages in combination with a preset function model;
wherein the preset function model comprises a quadratic function model, and the quadratic function model comprises a following function expression:
y=a(x+b)²+c, wherein y is the first result, x is the target read voltage, b is configured to represent a prediction parameter, a is a first parameter, and c is a second parameter.

18. The controller of claim 17, wherein the first parameter is a variable, the second parameter is a constant, the controller is configured to:
obtain the prediction parameter according to the two target read voltages and the two first results corresponding to the two target read voltages in combination with the quadratic function model; and
use the prediction parameter as the valley voltage.

19. The controller of claim 13, wherein the controller is configured to:
perform the read operation on the target codeword according to the valley voltage to obtain target data.

20. An operation method of a memory system, wherein the memory system comprises at least one memory device and a controller coupled to the memory device and configured to control the memory device, wherein the memory device comprises a memory cell array and a peripheral circuit coupled to the memory cell array, the memory cell array comprises a plurality of memory cells, and a preset number of memory cells in the plurality of memory cells form a codeword; and the operation method comprises:
performing, by the peripheral circuit, a read operation on a reference codeword to obtain a first result, and using the first result as a VT indicator, wherein the first result is configured to represent a number of bits that are flipped between two read results of the reference codeword at a first read voltage and a second read voltage, and a difference between the first read voltage and the second read voltage is less than a preset voltage;
obtaining, by the controller, at least one offset prediction according to the VT indicator in combination with a mapping table, wherein the mapping table comprises a mapping relationship between the VT indicator and the offset prediction; and
determining a valley voltage according to the offset prediction, wherein the valley voltage is used as a read voltage for performing the read operation on a target codeword.
